(19) United States
(12) Patent Application Publication
(10) Pub. No.: US 2024/0155902 A1
(43) Pub. Date: May 9, 2024

(54) DISPLAY PANEL AND DISPLAY DEVICE

(71) Applicant: Wuhan Tianma Microelectronics Co., Ltd., Wuhan (CN)

(72) Inventor: Fei LI, Wuhan (CN)

(73) Assignee: Wuhan Tianma Microelectronics Co., Ltd., Wuhan (CN)

(21) Appl. No.: 18/416,221

(22) Filed: Jan. 18, 2024

(30) Foreign Application Priority Data
Aug. 31, 2023 (CN) 202311121151.8

(51) Int. Cl. H10K 59/131; G09G 3/20; H10K 59/35

(52) U.S. Cl. CPC H10K 59/1315; G09G 3/20; H10K 59/353; G09G 2300/0426; G09G 2300/0842; G09G 2300/0861; G09G 2310/08; G09G 2320/0233; G09G 2320/0247; G09G 2330/021

(57) ABSTRACT

Provided are a display panel and a display device in the field of display technology. The display panel includes pixel driving circuits and signal lines; where a pixel driving circuit includes a drive transistor and a bias transistor, and the signal lines include bias signal lines; the drive transistor includes a gate, a first electrode and a second electrode; the bias transistor is electrically connected between a bias signal line and at least one of the first electrode or the second electrode of the drive transistor; and the bias signal lines include first bias signal sublines extending along a first direction and arranged along a second direction and second bias signal sublines extending along the second direction and arranged along the first direction, where the first direction intersects the second direction, and the first bias signal sublines and the second bias signal sublines are electrically connected.

### CROSS-REFERENCE TO RELATED APPLICATION(S)

This application claims priority to Chinese Patent Application No. 202311121151.8 filed Aug. 31, 2023, the disclosure of which is incorporated herein by reference in its entirety.

### TECHNICAL FIELD

The present disclosure relates to the field of display technology and, in particular, to a display panel and a display device.

### BACKGROUND

With the development of display technology, to reduce energy consumption, a display panel may be driven in a low-frequency driving manner when a static image is displayed. Meanwhile, to ensure the quality of image display, a pixel driving circuit is adjusted, for example, a pixel driving circuit with an 8T1C structure is provided. The pixel driving circuit with the 8T1C structure includes an added bias transistor relative to a conventional pixel driving circuit with a 7T1C structure, where the bias transistor is connected between a bias signal line and a first electrode or a second electrode of a drive transistor to provide a bias voltage signal to one electrode of the drive transistor when the bias transistor is selectively turned on.

In the related art, since the bias signal line is susceptible to the coupling interference of a change of a signal transmitted on another signal line, the quality of image display of the display panel is affected, that is, the quality of image display needs to be further improved.

### SUMMARY

To solve the preceding technical problem or at least partially solve the preceding technical problem, the present disclosure provides a display panel and a display device.

In a first aspect, the present disclosure provides a display panel including pixel driving circuits and signal lines.

A pixel driving circuit of the pixel driving circuits includes a drive transistor and a bias transistor, and the signal lines include bias signal lines.

The drive transistor includes a gate, a first electrode and a second electrode; and the bias transistor is electrically connected between a bias signal line of the bias signal lines and at least one of the first electrode or the second electrode of the drive transistor.

The bias signal lines include first bias signal sublines extending along a first direction and arranged along a second direction and second bias signal sublines extending along the second direction and arranged along the first direction, where the first direction intersects the second direction, and the first bias signal sublines and the second bias signal sublines are electrically connected.

In a second aspect, the present disclosure further provides a display device including the preceding display panel.

### BRIEF DESCRIPTION OF DRAWINGS

The drawings described herein, which are incorporated in the specification and form part of the specification, illustrate embodiments of the present disclosure and are intended to explain the principles of the present disclosure together with the description of the drawings.

To illustrate technical solutions in the embodiments of the present disclosure or in the related art more clearly, the drawings used in the description of the embodiments or the related art are briefly described below. Apparently, those of ordinary skill in the art may obtain other drawings based on the drawings described below on the premise that no creative work is done.

FIG. 1 is a structure diagram of a display panel according to an embodiment of the present disclosure.

FIG. 2 is a structure diagram of a pixel driving circuit according to an embodiment of the present disclosure.

FIG. 3 is a structure diagram of another pixel driving circuit according to an embodiment of the present disclosure.

FIG. 4 is a drive timing graph according to an embodiment of the present disclosure.

FIG. 5 is a structure diagram of staked films of a display panel according to an embodiment of the present disclosure.

FIG. 6 is a structure diagram of a partial layout of a display panel according to an embodiment of the present disclosure.

FIG. 7 is a structure diagram of a polysilicon semiconductor layer according to an embodiment of the present disclosure.

FIG. 8 is a structure diagram of a first gate metal layer according to an embodiment of the present disclosure.

FIG. 9 is a structure diagram of a capacitor metal layer according to an embodiment of the present disclosure.

FIG. 10 is a structure diagram of an oxide semiconductor layer according to an embodiment of the present disclosure.

FIG. 11 is a structure diagram of a second gate metal layer according to an embodiment of the present disclosure.

FIG. 12 is a structure diagram of a source-drain electrode layer according to an embodiment of the present disclosure.

FIG. 13 is a structure diagram of staked layers from a polysilicon semiconductor layer to a source-drain electrode layer according to an embodiment of the present disclosure.

FIG. 14 is a structure diagram of a first auxiliary metal layer according to an embodiment of the present disclosure.

FIG. 15 is a structure diagram of a second auxiliary metal layer according to an embodiment of the present disclosure.

FIG. 16 is a structure diagram of a reflective electrode layer according to an embodiment of the present disclosure.

FIG. 17 is a structure diagram of stacked layers from a first auxiliary metal layer to a reflective electrode layer according to an embodiment of the present disclosure.

FIG. 18 is a sectional view of FIG. 6 taken along A1A2.

FIG. 19 is a sectional view of FIG. 6 taken along B1B2.

FIG. 20 is a sectional view of FIG. 13 taken along A3A4.

FIG. 21 is a sectional view of FIG. 13 taken along B3B4.

FIG. 22 is a structure diagram of a partial layout of another display panel according to an embodiment of the present disclosure.

FIG. 23 is a structure diagram of another capacitor metal layer according to an embodiment of the present disclosure.

FIG. 24 is a structure diagram of another second gate metal layer according to an embodiment of the present disclosure.

FIG. 25 is a structure diagram of another source-drain electrode layer according to an embodiment of the present disclosure.

FIG. 26 is another structure diagram of staked layers from a polysilicon semiconductor layer to a source-drain electrode layer according to an embodiment of the present disclosure.

FIG. 27 is a sectional view of FIG. 26 taken along C3C4.

FIG. 28 is a sectional view of FIG. 22 taken along D1D2.

FIG. 29 is a sectional view of FIG. 22 taken along E1E2.

FIG. 30 is a sectional view of FIG. 22 taken along C1C2.

FIG. 31 is a structure diagram of another display panel according to an embodiment of the present disclosure.

FIG. 32 is a structure diagram of another display panel according to an embodiment of the present disclosure.

FIG. 33 is a structure diagram of another display panel according to an embodiment of the present disclosure.

FIG. 34 is a sectional view of another display panel according to an embodiment of the present disclosure.

FIG. 35 is a structure diagram of a display device according to an embodiment of the present disclosure.

### DETAILED DESCRIPTION

For a better understanding of the preceding object, features and advantages of the present disclosure, solutions of the present disclosure are further described below. It is to be noted that if not in collision, embodiments of the present disclosure and features therein may be combined with each other.

Many details are set forth in the following description for a full understanding of the present disclosure, and the present disclosure may be implemented in other manners not described herein. Apparently, the embodiments in the specification are part, not all, of the embodiments of the present disclosure.

In a display panel according to embodiments of the present disclosure, a pixel driving circuit based on an 8T1C structure can implement low-frequency driving and reduce the power consumption of the display panel. Moreover, bias signal lines include first bias signal sublines and second bias signal sublines extending in different directions and electrically connected in an intersection manner so that the overall size of the bias signal lines can be increased, the overall resistance of the bias signal lines can be reduced, and the bias signal lines have improved signal transmission stability and are less susceptible to the coupling interference of changes of signals transmitted on other signal lines, thereby facilitating the improvement of the quality of image display of the display panel.

A display panel and a display device according to embodiments of the present disclosure are illustrated below in conjunction with the drawings.

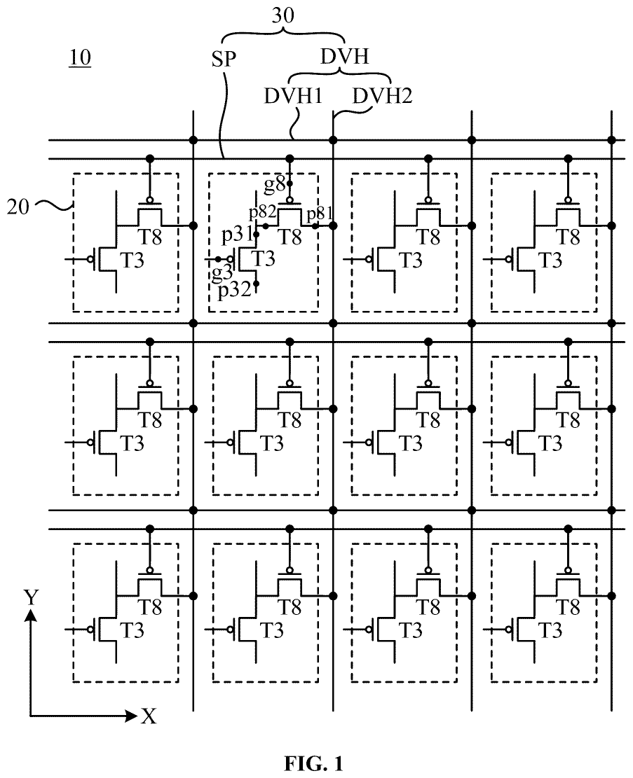

For example, FIG. 1 is a structure diagram of a display panel according to an embodiment of the present disclosure. Referring to FIG. 1, a display panel 10 includes pixel driving circuits 20 and signal lines 30, where a pixel driving circuit 20 includes a drive transistor T3 and a bias transistor T8, and the signal lines 30 include bias signal lines DVH and may also include bias control signal lines SP; the drive transistor T3 includes a gate g3, a first electrode p31 and a second electrode p32; and the bias transistor T8 is electrically connected between a bias signal line DVH and at least one of the first electrode p31 or the second electrode p32 of the drive transistor T3. That is, the bias transistor T8 is electrically connected between the bias signal line DVH and the first electrode p31 of the drive transistor T3, as shown in FIG. 1; and/or the bias transistor T8 is electrically connected between the bias signal line DVH and the second electrode p32 of the drive transistor T3, which is not shown in the drawings. The bias signal lines DVH include first bias signal sublines DVH1 extending along a first direction X and arranged along a second direction Y and second bias signal sublines DVH2 extending along the second direction Y and arranged along the first direction X, where the first direction X intersects the second direction Y, and the first bias signal sublines DVH1 and the second bias signal sublines DVH2 are electrically connected.

The signal lines 30 are configured to provide voltage signals and/or current signals for the pixel driving circuits 20; and the pixel driving circuit 20 is configured to drive a light-emitting element to emit light for display and control brightness of the light-emitting element. For example, the display panel 10 may include light-emitting elements arranged in an array and the pixel driving circuits 20 arranged in an array, and the pixel driving circuits 20 correspondingly drive different light-emitting elements to emit light for display according to target brightness so that the display panel 10 displays a target image.

The pixel driving circuit 20 may include a plurality of transistors which may include the drive transistor T3 and the bias transistor T8; a first electrode p81 of the bias transistor T8 is electrically connected to the bias signal line DVH, and a second electrode p82 of the bias transistor T8 is electrically connected to the first electrode p31 of the drive transistor T3, the second electrode p82 of the bias transistor T8 is electrically connected to the second electrode p32 of the drive transistor T3, or the second electrode p82 of the bias transistor T8 is electrically connected to the first electrode p31 and the second electrode p32 of the drive transistor T3. FIG. 1 illustrates that the second electrode p82 of the bias transistor T8 is electrically connected to the first electrode p31 of the drive transistor T3. A gate g8 of the bias transistor T8 is electrically connected to a bias control signal line SP. The pixel driving circuit 20 is set in various manners. For example, the pixel driving circuit 20 may be a circuit in a structural form such as “7T1C”, “7T2C” and “8T1C”, where “T” represents a transistor, and “C” represents a capacitor. Hereinafter, an example in which the pixel driving circuit 20 has the “8T1C” structure is used for description.

The bias transistor T8 is configured to be selectively turned on under the control of a bias control signal provided by the bias control signal line SP to transmit a bias voltage signal transmitted on the bias signal line DVH to the first electrode p31 or the second electrode p32 of the drive transistor T3.

The bias control signal may be one of scan signals; and each scan signal may include an enable level and a disable level, where the enable level may turn the transistor on, and the disable level may turn the transistor off. When the transistor is an n-type metal-oxide-semiconductor (NMOS) transistor, the enable level is a high level, and the disable level is a low level. When the transistor is a p-type metal-oxide-semiconductor (PMOS) transistor, the enable level is a low level, and the disable level is a high level. For other scan signals hereinafter, the type of the transistor, the enable level and the disable level being high or low and the transistor being turned on or off are understood in the same manner, and the details are not repeated hereinafter.

For example, the bias control signal includes the enable level and the disable level, the enable level may turn the bias transistor T8 on, and the disable level may turn the bias transistor T8 off. When the bias control signal line SP controls the bias transistor T8 to be turned on, the bias transistor T8 may transmit a bias voltage transmitted on the bias signal line DVH to the first electrode p31 of the drive transistor T3, so as to reset the first electrode p31 of the drive transistor T3 (that is, a second node N2 hereinafter), improve brightness of the first frame during image display, avoid too low brightness of the first frame, and ensure relatively good consistency of the image display. Additionally, before the gate g3 of the drive transistor T3 is reset, the bias transistor T8 is controlled to be turned on so that the bias voltage provided by the bias signal line DVH can be written to the first electrode p31 of the drive transistor T3 to refresh a potential of the first electrode p31 of the drive transistor T3. In this manner, the device characteristics of the drive transistor T3 are set to a determined initial state, thereby eliminating an effect of a data signal written in a previous frame on the device characteristics of the drive transistor T3. After a data voltage is written to the drive transistor T3, a voltage of the first electrode p31 of the drive transistor T3 is leaked, and the leakage is more obvious in the case of low-frequency driving, causing a relatively large drift of the potential of the first electrode p31 of the drive transistor T3. In this case, the bias transistor T8 is controlled to be turned on, and the bias voltage is written to the first electrode p31 of the drive transistor T3 through the bias transistor T8 so that a bias state of the drive transistor T3 can remain consistent with a bias state when the data voltage is written, so as to improve the stability of a working state of the drive transistor T3, reduce a low-frequency flicker, and improve the image display effect of the display panel 10.

In the embodiments of the present disclosure, the bias signal lines DVH may include the first bias signal sublines DVH1 and the second bias signal sublines DVH2 extending in different directions and electrically connected in an intersection manner, where the first bias signal sublines DVH1 extend along the first direction X and are arranged along the second direction Y, and the second bias signal sublines DVH2 extend along the second direction Y and are arranged along the first direction X, where the first direction X intersects the second direction Y.

For example, a plurality of first bias signal sublines DVH1 and a plurality of second bias signal sublines DVH2 may be provided, where the plurality of first bias signal sublines DVH1 and the plurality of second bias signal sublines DVH2 may intersect at a plurality of positions. The first bias signal sublines DVH1 and the second bias signal sublines DVH2 may be electrically connected at all the intersection positions, as shown in FIG. 1. Alternatively, the first bias signal sublines DVH1 and the second bias signal sublines DVH2 may be electrically connected at part of the intersection positions. Specifically, each first bias signal subline DVH1 may be connected to at least one second bias signal subline DVH2, and each second bias signal subline DVH2 may be connected to at least one first bias signal subline DVH1.

In some embodiments, the first direction X is perpendicular to the second direction Y, for example, the first direction X is a row direction and the second direction Y is a column direction. In some other embodiments, the first direction X and the second direction Y are not perpendicular and are at an angle greater than 0° and less than 90°.

In the display panel 10 according to the embodiments of the present disclosure, the bias signal lines DVH include the first bias signal sublines DVH1 and the second bias signal sublines DVH2 extending in different directions and electrically connected in the intersection manner so that the overall size of the bias signal lines DVH can be increased, the overall resistance of the bias signal lines DVH can be reduced, and the bias signal lines DVH have improved signal transmission stability and are less susceptible to the coupling interference of other signal lines 30 (such as the bias control signal lines SP), thereby facilitating the improvement of the quality of image display of the display panel 10.

For example, when a display region of the display panel includes an opening, the embodiments of the present disclosure can alleviate the problem of a display split screen at the position of the opening in the display region. For example, a camera or another structural component may be disposed at the position of the opening in the display region, which is not limited here.

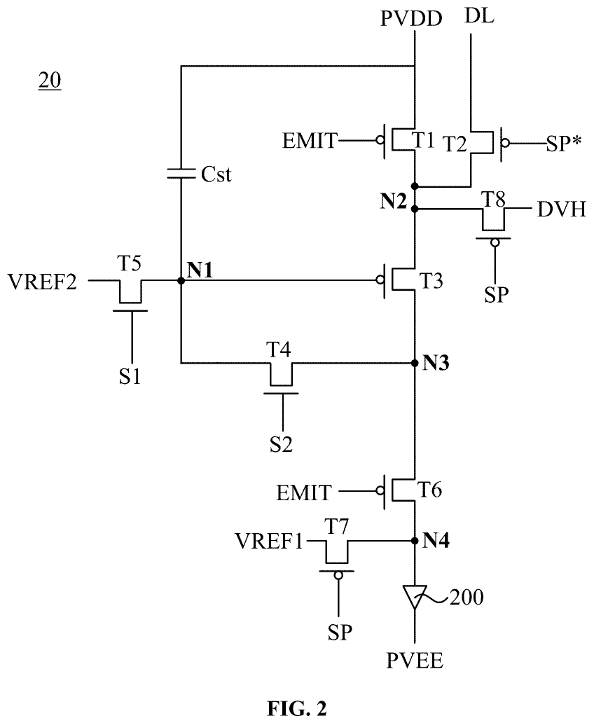

For example, the first electrode p31 of the drive transistor T3 may be electrically connected to a first power line PVDD. Specifically, the first electrode p31 of the drive transistor T3 may be electrically connected to the first power line PVDD directly, or the first electrode p31 of the drive transistor T3 may be electrically connected to the first power line PVDD indirectly via an element such as a thin-film transistor and a capacitor, which is illustrated below with reference to FIG. 2.

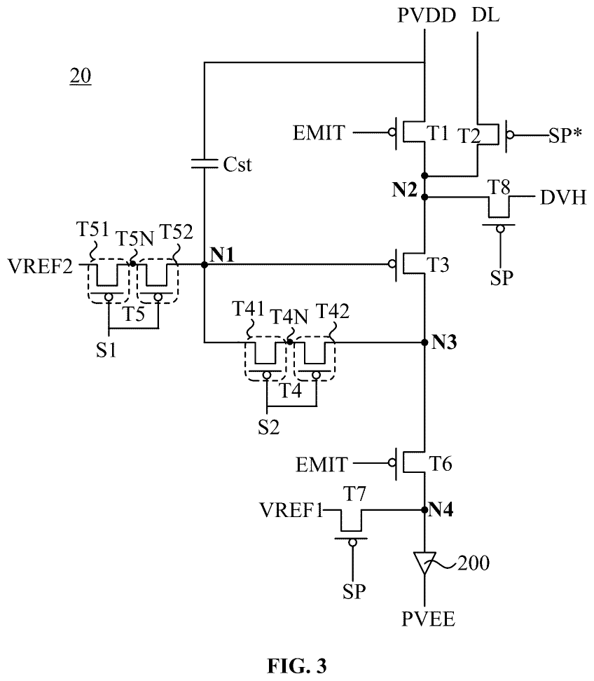

For example, FIG. 2 is a structure diagram of a pixel driving circuit according to an embodiment of the present disclosure, and FIG. 3 is a structure diagram of another pixel driving circuit according to an embodiment of the present disclosure. Referring to FIGS. 2 and 3, the pixel driving circuit 20 includes a plurality of thin-film transistors which may include a power write transistor T1, a data write transistor T2, the drive transistor T3, a compensation transistor T4, a first reset transistor T7, a second reset transistor T5, a light emission control transistor T6 and the bias transistor T8; and the pixel driving circuit may also include a storage capacitor Cst. Correspondingly, the signal lines 30 may include scan signal lines, reset signal lines, power signal lines and data lines DL, where the scan signal lines include first scan signal lines S1, second scan signal lines S2, light emission control scan signal lines EMIT, third scan signal lines SP* and the bias control signal lines SP, the reset signal lines includes at least one of first reset signal lines VREF1 or second reset signal lines VREF2, and the power signal lines includes first power lines PVDD and second power lines PVEE.

A first electrode of the power write transistor T1 is electrically connected to the first power line PVDD, a second electrode of the power write transistor T1 is electrically connected to the second node N2, and a gate of the power write transistor T1 is electrically connected to a light emission control scan signal line EMIT. A first electrode of the data write transistor T2 is electrically connected to a data line DL, a second electrode of the data write transistor T2 is electrically connected to the second node N2, and a gate of the data write transistor T2 is electrically connected to a third scan signal line SP*. The first electrode of the drive transistor T3 is electrically connected to the second node N2, the second electrode of the drive transistor T3 is electrically connected to a third node N3, and the gate of the drive transistor T3 is electrically connected to a first node N1. A first electrode of the compensation transistor T4 is electrically connected to the first node N1, a second electrode of the compensation transistor T4 is electrically connected to the third node N3, and a gate of the compensation transistor T4 is electrically connected to a second scan signal line S2. A first electrode of the second reset transistor T5 is electrically connected to a second reset signal line VREF2, a second electrode of the second reset transistor T5 is electrically connected to the first node N1, and a gate of the second reset transistor T5 is electrically connected to a first scan signal line S1. A first electrode of the light emission control transistor T6 is electrically connected to the third node N3, a second electrode of the light emission control transistor T6 is electrically connected to a fourth node N4, and a gate of the light emission control transistor T6 is electrically connected to the light emission control scan signal line EMIT. A first electrode of the first reset transistor T7 is electrically connected to a first reset signal line VREF1, a second electrode of the first reset transistor T7 is electrically connected to the fourth node N4, and a gate of the first reset transistor T7 is electrically connected to the bias control signal line SP. The first electrode of the bias transistor T8 is electrically connected to the bias signal line DVH, the second electrode of the bias transistor T8 is electrically connected to the second node N2, and the gate of the bias transistor T8 is electrically connected to the bias control signal line SP. A first plate of the storage capacitor Cst is electrically connected to the first node N1, and a second plate of the storage capacitor Cst is electrically connected to the first power line PVDD. Thus, the pixel driving circuit 20 with the 8T1C structure is implemented.

It is to be understood that when the compensation transistor T4 and the second reset transistor T5 are each an indium gallium zinc oxide (IGZO) transistor and a top and bottom double-gate transistor, the gates are controlled by two scan signal lines which are electrically connected in a non-display region and disposed in different films in the display region. The two scan signal lines are named with the same reference numeral in the present application.

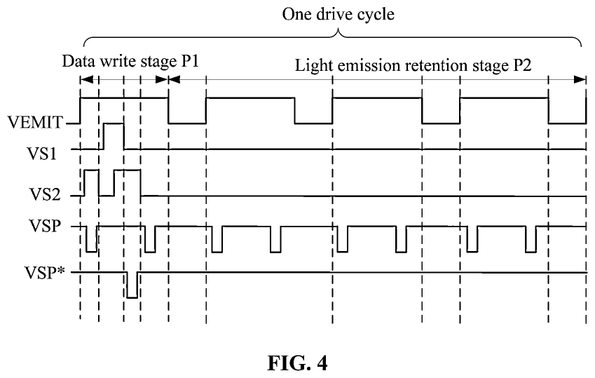

Specifically, a working process of the pixel driving circuit 20 is illustrated with reference to FIGS. 2 and 4. A first scan signal VS1 on the first scan signal line S1 controls the second reset transistor T5 in the pixel driving circuit 20 to be turned on or off, and when the second reset transistor T5 is turned on, the potential of the gate of the drive transistor T3 is reset, that is, a second reset signal on the second reset signal line VREF2 is transmitted to the second reset transistor T5 to reset the connection node (first node N1) of the drive transistor T3, the second reset transistor T5, the compensation transistor T4 and the storage capacitor Cst. A third scan signal VSP* on the third scan signal line SP* controls the data write transistor T2 in the pixel driving circuit 20 to be turned on or off, and when the data write transistor T2 is turned on, a data signal on the data line DL is written to the gate of the drive transistor T3. A second scan signal VS2 on the second scan signal line S2 controls the compensation transistor T4 to be turned on or off, and when the compensation transistor T4 is turned on, a threshold voltage of the drive transistor T3 is compensated for. Meanwhile, the bias control signal line SP controls the first reset transistor T7 to be turned on or off, and when the first reset transistor T7 is turned on, an anode of the light-emitting element 200 connected to the pixel driving circuit 20 is reset, that is, a first reset signal on the first reset signal line VREF1 is transmitted to the anode of the light-emitting element 200. Alight emission control scan signal VEMIT on the light emission control scan signal line EMIT controls the power write transistor T1 and the light emission control transistor T6 to be turned on or off, and when the power write transistor T1 and the light emission control transistor T6 are controlled to be turned on, a first power signal transmitted on the first power line PVDD is transmitted to the light-emitting element 200, thereby implementing the display and light emission of the light-emitting element 200. The bias control signal VSP on the bias control signal line SP controls the bias transistor T8 to be turned on or off, and when the bias transistor T8 is turned on, bias adjustment is performed on the drive transistor T3, that is, a bias signal on the bias signal line DVH is transmitted to the bias transistor T8 to perform the bias adjustment on the connection node (second node N2) of the drive transistor T3, the power write transistor T1 and the data write transistor T2, thereby ensuring the working stability of the drive transistor T3.

As shown in FIG. 2, the pixel driving circuit 20 includes various types of thin-film transistor, and an oxide transistor (such as the IGZO transistor) and a low-temperature polysilicon (LTPS) transistor may be present at the same time. The oxide transistor has the advantages of a small leakage current and the like, and the LTPS transistor has the advantages of a high switching speed, a high carrier mobility, low power and the like. The display panel uses the technique of low temperature polycrystalline oxide (LTPO) that combines LTPS with IGZO. The display panel 10 has not only the advantages of a high resolution, a high response speed, high brightness, a high aperture ratio and the like of an LTPS display panel but also the advantages of a small leakage current and the like of IGZO.

As shown in FIG. 3, each transistor in the pixel driving circuit 20 may be the LTPS transistor, and the display panel 10 requires a simple preparation technique and a relatively low film design cost. The specific type of the display panel 10 is not limited in the embodiments of the present disclosure and may be adaptively adjusted according to actual production requirements.

In some embodiments, all the thin-film transistors in the pixel driving circuit 20 are of the same channel type, for example, p-type transistors or n-type transistors, as shown in FIG. 2. Alternatively, the thin-film transistors in the pixel driving circuit 20 may be of different channel types, as shown in FIG. 3. In conjunction with FIGS. 2 and 3 and the above description, the oxide transistor is an n-type transistor, and the LTPS transistor is a p-type transistor.

For example, the power write transistor T1, the data write transistor T2, the drive transistor T3, the first reset transistor T7, the light emission control transistor T6 and the bias transistor T8 may be p-type transistors. For example, the power write transistor T1, the data write transistor T2, the drive transistor T3, the first reset transistor T7, the light emission control transistor T6 and the bias transistor T8 may be PMOS transistors. For example, the power write transistor T1, the data write transistor T2, the drive transistor T3, the first reset transistor T7, the light emission control transistor T6 and the bias transistor T8 may be polysilicon transistors, and channels of the polysilicon transistors may be constructed of polysilicon. The polysilicon transistors may be LTPS transistors. The polysilicon transistors have a high electron mobility and thus have the characteristic of fast driving.

The compensation transistor T4 and the second reset transistor T5 may be n-type transistors. For example, the compensation transistor T4 and the second reset transistor T5 may be NMOS transistors. For example, channels of the compensation transistor T4 and the second reset transistor T5 may be constructed of an oxide semiconductor. For example, the oxide semiconductor may include indium gallium zinc oxide (IGZO). Compared with polysilicon, an oxide semiconductor transistor has a low charge mobility. Therefore, an amount of leakage currents generated in a cutoff state of the oxide semiconductor transistor is smaller than an amount of leakage currents generated in a cutoff state of the polysilicon transistor.

Therefore, besides that the bias voltage on the bias signal line DVH is provided for the first electrode p31 and/or the second electrode p32 of the drive transistor T3, the compensation transistor T4 and the second reset transistor T5 may be configured to be oxide semiconductor transistors, for example, IGZO transistors, so as to reduce an effect of the leakage currents of the second reset transistor T5 and the compensation transistor T4 on the potential of the gate g3 of the drive transistor T3, improve the stability of the working state of the drive transistor T3, and improve the image display effect of the display panel 10.

It is to be understood that the first node N1, the second node N2, the third node N3 and the fourth node N4 may be virtual connection nodes or actual connection nodes.

For example, FIG. 4 is a drive timing graph according to an embodiment of the present disclosure, which shows signals provided for the pixel driving circuit shown in FIG. 2 within one drive cycle. Referring to FIG. 4, for example, in the pixel driving circuit 20, the compensation transistor T4 is the n-type transistor and the light emission control transistor T6 is the p-type transistor, and the gate of the light emission control transistor T6 is electrically connected to the light emission control scan signal line EMIT. the disable level of the light emission control scan signal VEMIT is the high level, and the enable level of the light emission control scan signal VEMIT is the low level; and the enable level of the second scan signal VS2 transmitted on the second scan signal line S2 is the high level, and the disable level of the second scan signal S2 transmitted on the second scan signal line S2 is the low level. In one drive cycle of the pixel driving circuit 20, the light emission control scan signal VEMIT transmitted on the light emission control scan signal line EMIT includes a plurality of disable level stages and a plurality of enable level stages, where the disable level stages and the enable level stages are alternated. When the light emission control scan signal VEMIT is at the disable level, the light emission control transistor T6 is turned off, and when the light emission control scan signal VEMIT is at the enable level, the light emission control transistor T6 is turned on. The drive cycle of the pixel driving circuit 20 includes a data write stage P1 and a light emission retention stage P2, where the data write stage P1 includes one disable level stage of the light emission control scan signal VEMIT, the light emission control scan signal VEMIT includes a plurality of disable level stages and a plurality of enable level stages in the light emission retention stage P2, the second scan signal VS2 transmitted on the second scan signal line S2 includes at least one high level stage in the data write stage P1 to transmit the data signal DL to the gate of the drive transistor T3, and the second scan signal VS2 transmitted on the second scan signal line S2 is at the low level in the light emission retention stage P2 to control the compensation transistor T4 to be turned off.

It is to be understood that in the light emission retention stage P2, two enable level stages of VSP corresponding to one disable level stage of VEMIT in FIG. 4 may be adjusted to one enable level stage, and a duration of the enable level stage may be increased or decreased relative to a duration of one enable level stage of VSP in the data write stage P1. The light emission control scan signal VEMIT has a greater frequency than the signal transmitted on the second scan signal line S2.

FIG. 4 shows the drive timing in a low-frequency driving mode. In practice, when the display panel is required to have different refresh rates, a duration of the light emission retention stage P2 may be adjusted appropriately. When the display panel needs a high-frequency driving mode, the duration of the light emission retention stage P2 may be reduced as much as possible relative to the low-frequency driving mode. For example, one disable level stage of VEMIT adjacent to the data write stage P1 is retained and other stages in the light emission retention stage P2 may be no longer set, and the next data write stage P1 then begins.

It is to be noted that the pixel driving circuit shown in FIGS. 2 and 3 is an example and is not intended to limit the embodiments of the present disclosure. In other embodiments, the display panel 10 may include the pixel driving circuit 20 with another circuit structure. The drive timing shown in FIG. 4 is an example and is not intended to limit the embodiments of the present disclosure. In other embodiments, the display panel 10 may be driven by another timing.

In the display panel 10, the first reset signal line VREF1 and the second reset signal line VREF2 may transmit the same reset signal, that is, the first node N1 and the fourth node N4 may be reset by one reset signal. In other embodiments, the first reset signal line VREF1 and the second reset signal line VREF2 may transmit different reset signals, that is, a reset voltage of the first node N1 may be different from a reset voltage of the fourth node N4, which is not limited here.

As shown in FIG. 3, in the display panel 10, the compensation transistor T4 and the second reset transistor T5 may each be a double-gate transistor, so as to reduce the leakage current of the transistor and improve the display effect of the display panel.

For example, the compensation transistor T4 may include a first sub-transistor T41 and a second sub-transistor T42, where a first electrode of the first sub-transistor T41 is electrically connected to the gate of the drive transistor T3, a second electrode of the first sub-transistor T41 is electrically connected to a first electrode of the second sub-transistor T42, and a second electrode of the second sub-transistor T42 is electrically connected to the second electrode of the drive transistor T3; a gate of the first sub-transistor T41 and a gate of the second sub-transistor T42 are connected to the second scan signal line S2; and an intermediate node T4N is located at a connection between the second electrode of the first sub-transistor T41 and the first electrode of the second sub-transistor T42.

Thus, the structure of the compensation transistor T4 may be understood as a structure of two sub-transistors connected in series. Specifically, the compensation transistor T4 includes the first sub-transistor T41 and the second sub-transistor T42 connected to each other, the first electrode of the first sub-transistor T41 serves as the first electrode of the compensation transistor T4 to be electrically connected to the gate of the drive transistor T3, the second electrode of the second sub-transistor T42 serves as the second electrode of the compensation transistor T4 to be electrically connected to the second electrode of the drive transistor T3, and the second electrode of the first sub-transistor T41 is electrically connected to the first electrode of the second sub-transistor T42, so as to connect the two sub-transistors in series; the gate of the first sub-transistor T41 and the gate of the second sub-transistor T42 are both connected to the second scan signal line S2, that is, the gate of the first sub-transistor T41 and the gate of the second sub-transistor T42 are connected to the same second scan signal line S2, and the first sub-transistor T41 and the second sub-transistor T42 are turned off or on based on the same second scan signal VS2; and the connection where the second electrode of the first sub-transistor T41 is electrically connected to the first electrode of the second sub-transistor T42 may be understood as the intermediate node T4N of the compensation transistor T4.

In a film structure of the display panel 10, an active portion of the first sub-transistor T41 and an active portion of the second sub-transistor T42 together form an active portion of the compensation transistor T4. In the case where the active portion has semiconductor characteristics, the active portion of the first sub-transistor T41 may include a channel region and the first electrode and the second electrode disposed on two sides of the channel region separately, the active portion of the second sub-transistor T42 may also include a channel region and the first electrode and the second electrode disposed on two sides of the channel region separately, and a connection between the channel region of the first sub-transistor T41 and the channel region of the second sub-transistor T42 may be understood as the intermediate node T4N of the compensation transistor T4. The channel region may be understood as a region where the gate and the active portion of the transistor overlap.

It is to be noted that the position of the intermediate node T4N of the compensation transistor T4 in the film structure of the display panel is not described in detail in the embodiments of the present disclosure and may be specifically set according to a layout of the panel, which is not limited here.

Similarly, the second reset transistor T5 may include a third sub-transistor T51 and a fourth sub-transistor T52, where a first electrode of the third sub-transistor T51 is electrically connected to the second reset signal line VREF2, a second electrode of the third sub-transistor T51 is electrically connected to a first electrode of the fourth sub-transistor T52, and a second electrode of the fourth sub-transistor T52 is electrically connected to the gate of the drive transistor T3; a gate of the third sub-transistor T51 and a gate of the fourth sub-transistor T52 are connected to the first scan signal line S1; and an intermediate node T5N is located at a connection between the second electrode of the third sub-transistor T51 and the first electrode of the fourth sub-transistor T52.

Thus, the structure of the second reset transistor T5 may be understood as a structure of two sub-transistors connected in series. Specifically, the second reset transistor T5 includes the third sub-transistor T51 and the fourth sub-transistor T52 connected to each other, the first electrode of the third sub-transistor T51 serves as the first electrode of the second reset transistor T5 to be electrically connected to the second reset signal line VREF2, the second electrode of the fourth sub-transistor T52 serves as the second electrode of the second reset transistor T5 to be electrically connected to the gate of the drive transistor T3, and the second electrode of the third sub-transistor T51 is electrically connected to the first electrode of the fourth sub-transistor T52, so as to connect the two sub-transistors in series; the gate of the third sub-transistor T51 and the gate of the fourth sub-transistor T52 are connected to the same first scan signal line S1, that is, the gate of the third sub-transistor T51 and the gate of the fourth sub-transistor T52 are connected to the same first scan signal line S1, and the third sub-transistor T51 and the fourth sub-transistor T52 are turned off or on based on the same first scan signal VS1; and the connection where the second electrode of the third sub-transistor T51 is electrically connected to the first electrode of the fourth sub-transistor T52 may be understood as the intermediate node T5N of the second reset transistor T5.

In the film structure of the display panel 10, an active portion of the third sub-transistor T51 and an active portion of the fourth sub-transistor T52 together form an active portion of the second reset transistor T5. In the case where the active portion has semiconductor characteristics, the active portion of the third sub-transistor T51 may include a channel region and the first electrode and the second electrode disposed on two sides of the channel region separately, the active portion of the fourth sub-transistor T52 may also include a channel region and the first electrode and the second electrode disposed on two sides of the channel region separately, and a connection between the channel region of the third sub-transistor T51 and the channel region of the fourth sub-transistor T52 may be understood as the intermediate node T5N of the second reset transistor T5. The channel region may be understood as a region where the gate and the active portion of the transistor overlap.

It is to be noted that the position of the intermediate node T5N of the second reset transistor T5 in the film structure of the display panel is not described in detail in the embodiments of the present disclosure and may be specifically set according to the layout of the panel, which is not limited here.

In the field of display technology, films are stacked so as to implement devices such as the thin-film transistors and the storage capacitor in the pixel driving circuit 20. For the sake of clarity, a film stacking manner of the display panel 10 is illustrated in the embodiments of the present disclosure.

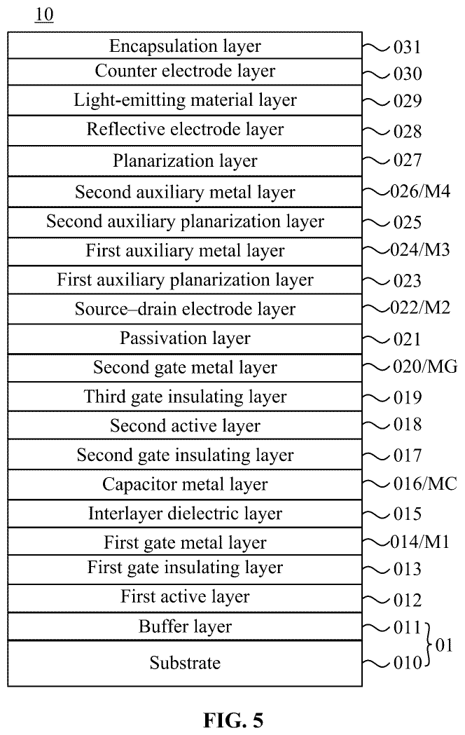

For example, FIG. 5 is a structure diagram of staked films of a display panel according to an embodiment of the present disclosure, which shows the structure of staked films of a low-temperature polysilicon oxide (LTPO) panel with a narrow bezel and fan-out wires in the display region (fan-out in AA (FIAA)). Referring to FIG. 5, the display panel 10 may include a substrate 010 and a buffer layer 011, a first active layer 012, a first gate insulating layer 013, a first gate metal layer 014, an interlayer dielectric layer 015, a capacitor metal layer 016, a second gate insulating layer 017, a second active layer 018, a third gate insulating layer 019, a second gate metal layer 020, a passivation layer 021, a source-drain electrode layer 022, a first auxiliary planarization layer 023, a first auxiliary metal layer 024, a second auxiliary planarization layer 025, a second auxiliary metal layer 026, a planarization layer 027, a reflective electrode layer 028, a light-emitting material layer 029, a counter electrode layer 030 and an encapsulation layer 031, which are stacked on a side of the substrate 010. Herein, the first gate metal layer 014 may also be labeled M1, the capacitor metal layer 016 may also be labeled MC, the second gate metal layer 020 may also be labeled MG, the source-drain electrode layer 022 may also be labeled M2, the first auxiliary metal layer may also be labeled M3, and the second auxiliary metal layer 026 may also be labeled M4.

The substrate 010 is configured to support films disposed on the substrate 010. The substrate 010 may include a rigid substrate such as glass and a silicon wafer or may include a flexible substrate such as thin glass, stainless steel and polyimide, which is not limited here.

The buffer layer 011 is configured to flatten and passivate the substrate 010 to facilitate the smooth deposition of the subsequent function films and avoid an effect of components in the substrate 010 on the performance of the subsequent films.

The first active layer 012 and the second active layer 018 are each a semiconductor layer. For example, the first active layer 012 may be a silicon semiconductor layer such as a polysilicon (poly-Si) semiconductor layer; and the second active layer 018 may be an oxide semiconductor layer such as an IGZO semiconductor layer.

The first gate metal layer 014, the capacitor metal layer 016, the second gate metal layer 020, the source-drain electrode layer 022, the first auxiliary metal layer 024 and the second auxiliary metal layer 026 may be metal layers and are patterned to form the pixel driving circuits, the signal lines and other conductor structures in the display panel. The passivation layer 021 is configured to optimize the electrical performance of conductor structures covered by the passivation layer 021.

The reflective electrode layer 028 may be a composite film such as an indium tin oxide (ITO)/silver (Ag)/ITO layer. The counter electrode layer 030 may be a relatively thin metal composite layer such as a magnesium (Mg)/silver (Ag) layer, so as to improve light transmittance and facilitate the exit of light generated by the light-emitting material layer 029 in the light-emitting element 200. The light-emitting material layer 029 is configured to be driven by the pixel driving circuit 20 to emit light with the target brightness and a target color based on a photoelectric effect and in response to signals provided by the reflective electrode layer 028 and the counter electrode layer 030 so that the display panel 10 displays the target image.

The first gate insulating layer 013, the interlayer dielectric layer 015, the second gate insulating layer 017, the third gate insulating layer 019 and the passivation layer 021 are generally inorganic insulating layers, and the first auxiliary planarization layer 023, the second auxiliary planarization layer 025 and the planarization layer 027 are generally organic insulating layers. Vias are disposed in layers so that corresponding conductor structures are electrically connected through the vias, so as to form the devices in the pixel driving circuit. The encapsulation layer 031 may include an inorganic layer, an organic layer and an inorganic layer to implement an encapsulation function.

It is to be noted that the number of films and a stacking sequence of the films are illustrative, and a film may be added or deleted or positions or the sequence of the films may be adjusted based on actual requirements; and the films may be made of other materials known to those skilled in the art, which may be set based on the requirements of the display panel 10 and are not limited here.

Additionally, FIG. 5 shows only an example of the structure of stacked films of the display panel that combines LTPO with FIAA, which is not intended to limit the embodiments of the present disclosure. In other embodiments, the display panel may employ other structures of stacked films, such as a film structure of an LTPS panel and a film structure of a panel that combines LTPS with FIAA, which are not limited here.

Hereinafter, the display panel is illustrated in conjunction with the plane patterning of the metal layers and the semiconductor layers in the display panel.

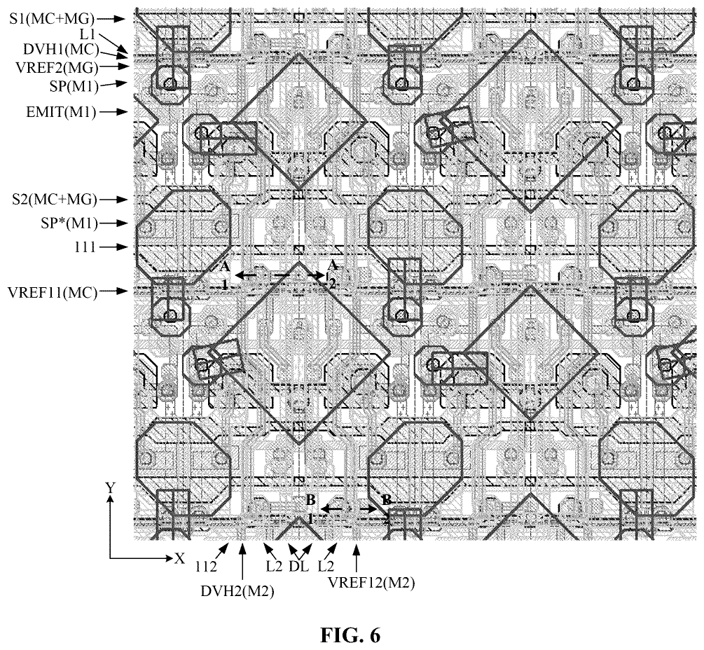

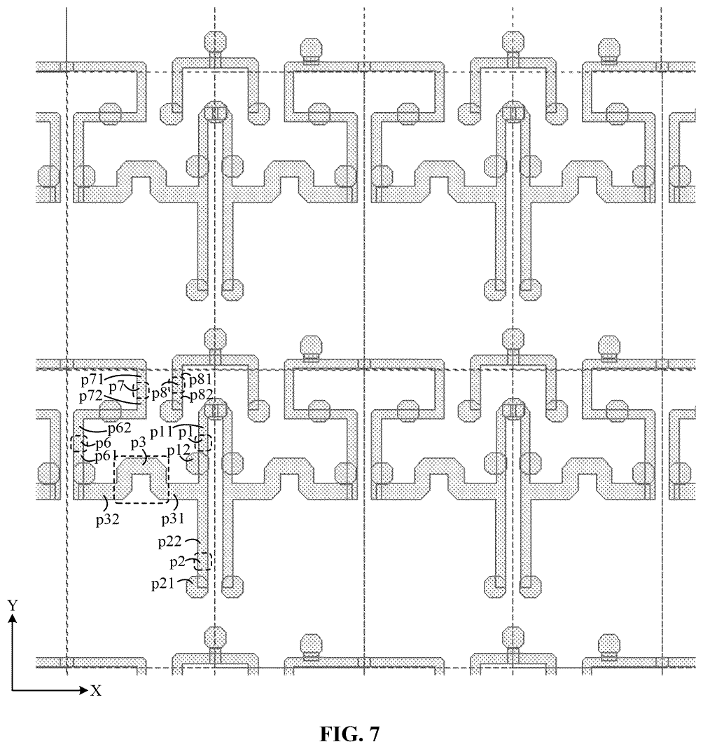

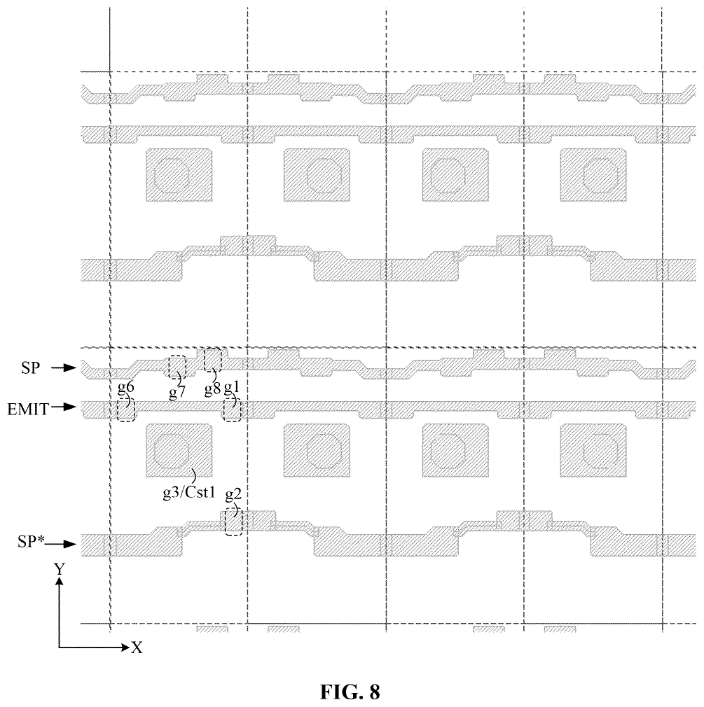

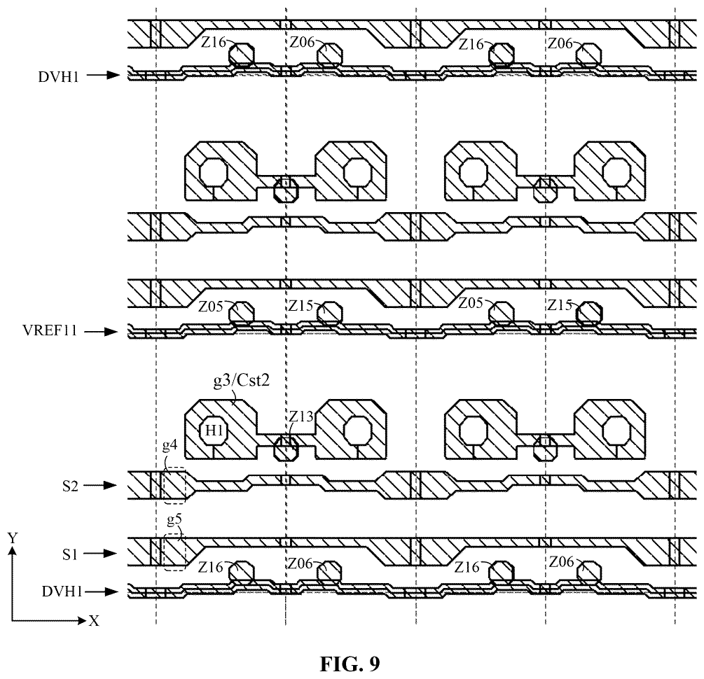

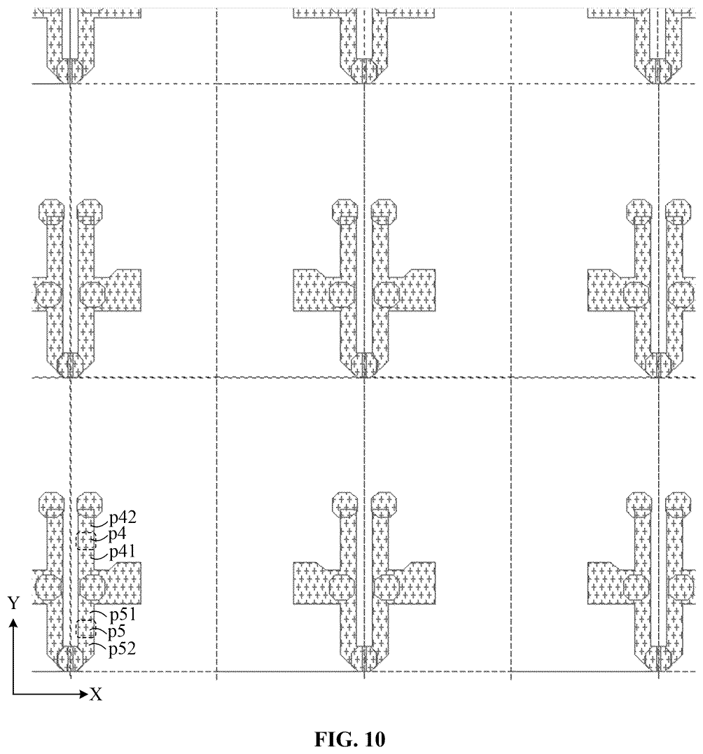

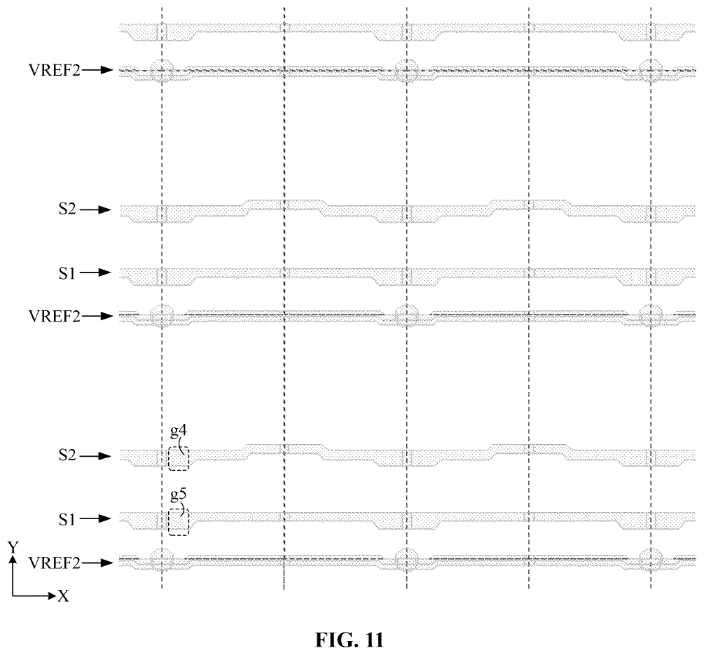

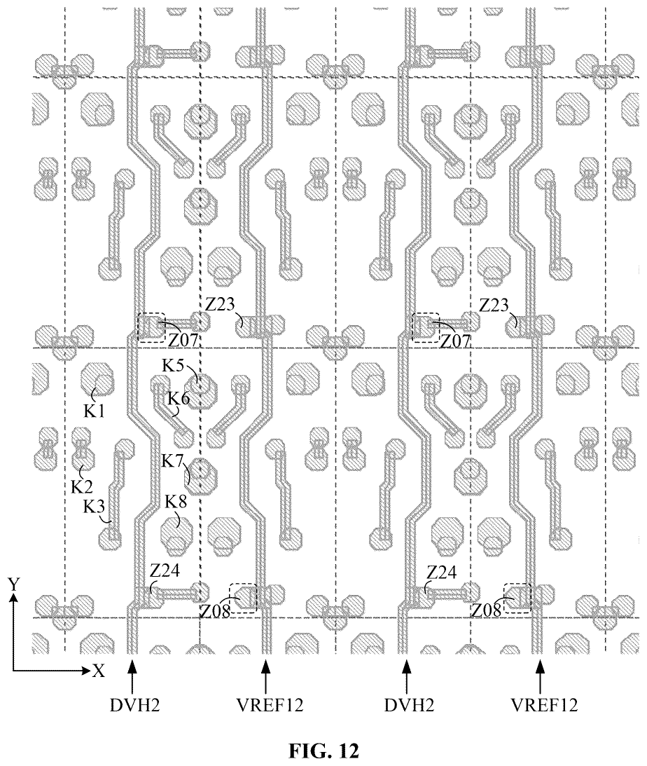

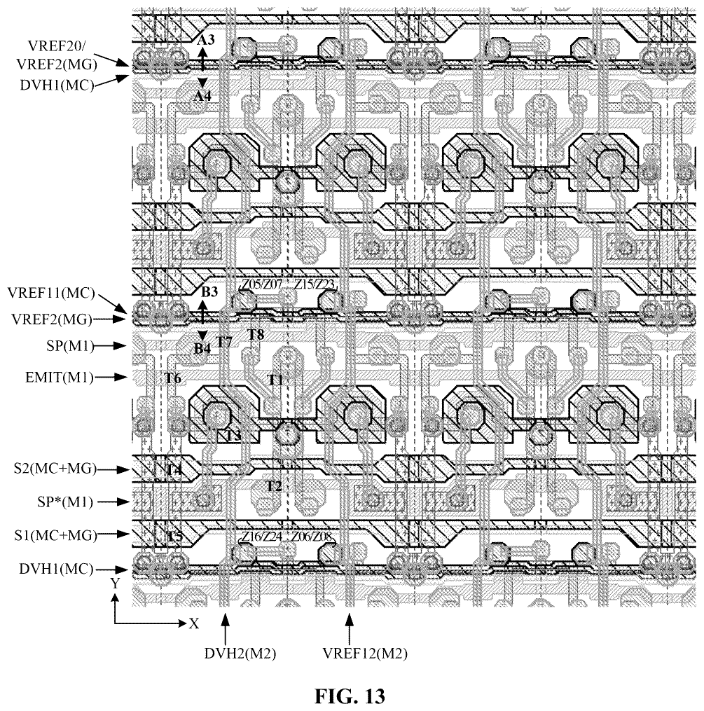

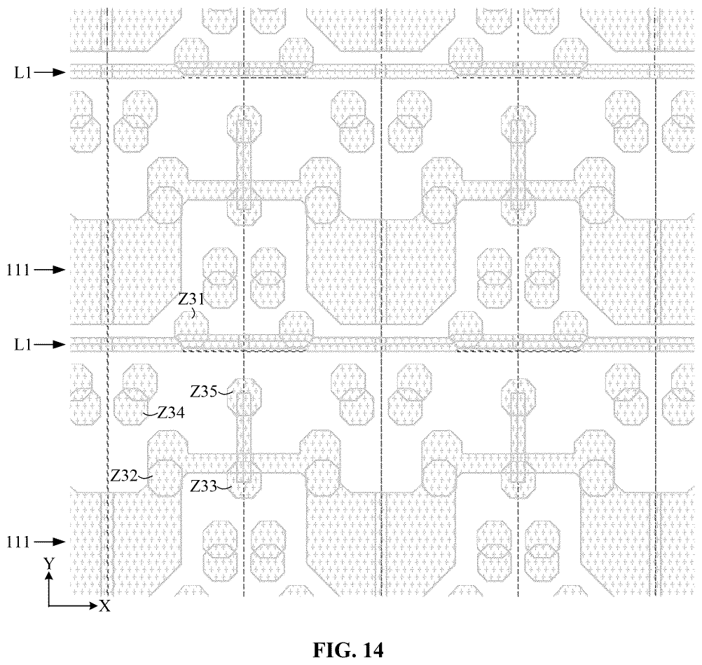

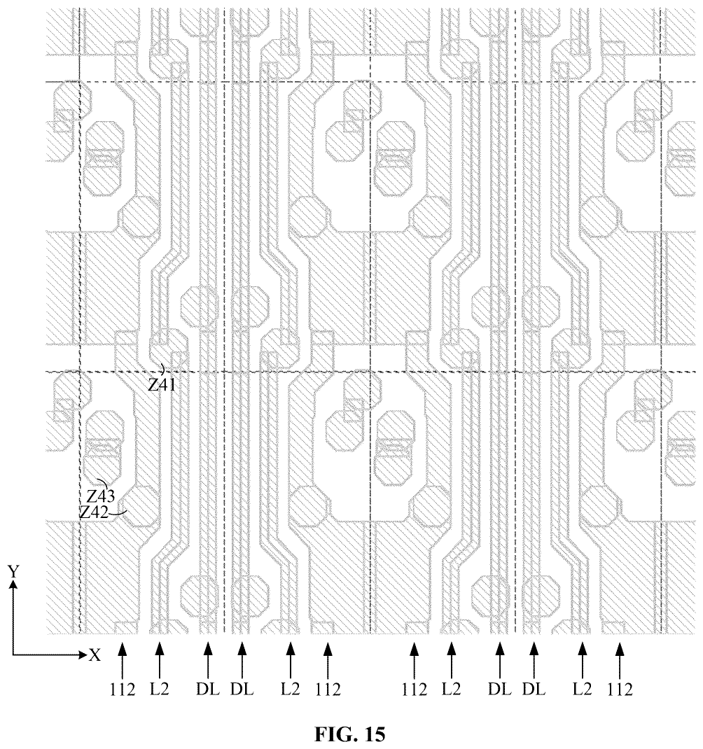

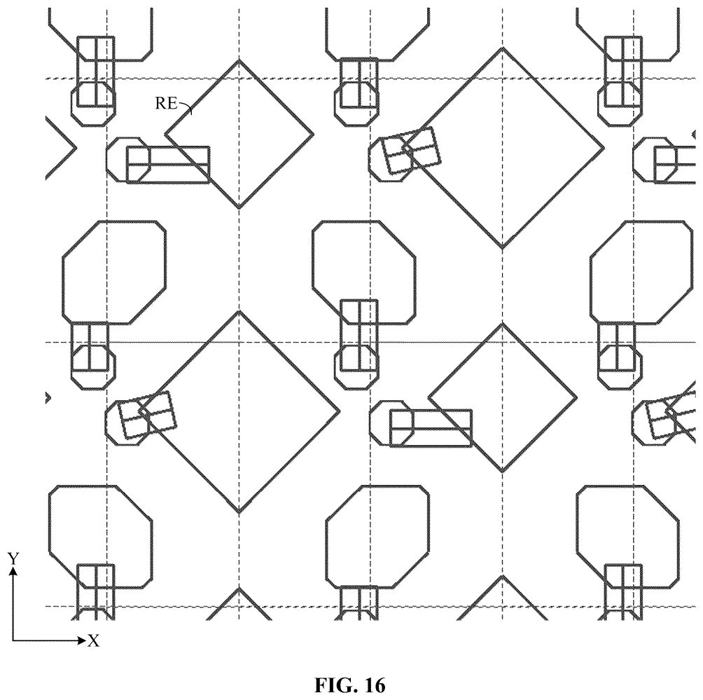

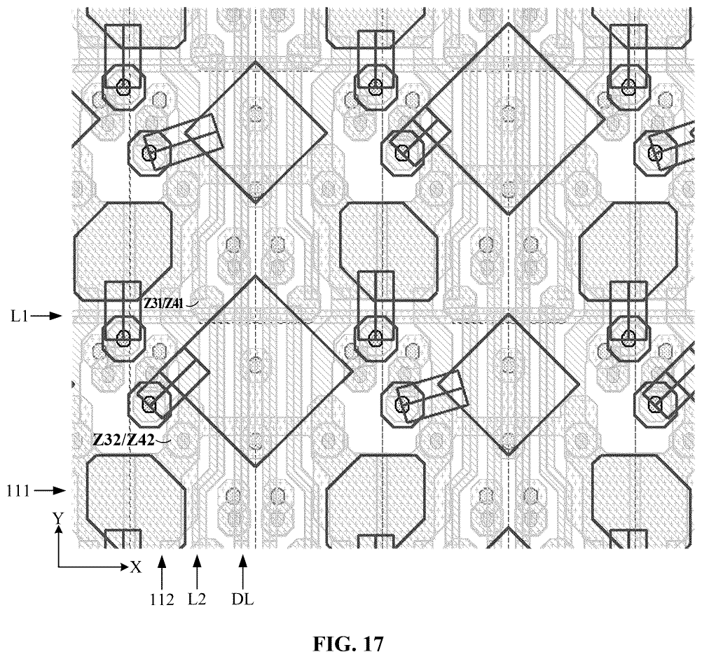

For example, FIG. 6 is a structure diagram of a partial layout of a display panel according to an embodiment of the present disclosure, FIG. 7 is a structure diagram of a polysilicon semiconductor layer according to an embodiment of the present disclosure, FIG. 8 is a structure diagram of a first gate metal layer according to an embodiment of the present disclosure, FIG. 9 is a structure diagram of a capacitor metal layer according to an embodiment of the present disclosure, FIG. 10 is a structure diagram of an oxide semiconductor layer according to an embodiment of the present disclosure, FIG. 11 is a structure diagram of a second gate metal layer according to an embodiment of the present disclosure, FIG. 12 is a structure diagram of a source-drain electrode layer according to an embodiment of the present disclosure, FIG. 13 is a structure diagram of staked layers from a polysilicon semiconductor layer to a source-drain electrode layer according to an embodiment of the present disclosure, FIG. 14 is a structure diagram of a first auxiliary metal layer according to an embodiment of the present disclosure, FIG. 15 is a structure diagram of a second auxiliary metal layer according to an embodiment of the present disclosure, FIG. 16 is a structure diagram of a reflective electrode layer according to an embodiment of the present disclosure, and FIG. 17 is a structure diagram of stacked layers from a first auxiliary metal layer to a reflective electrode layer according to an embodiment of the present disclosure. Based on FIG. 5, FIGS. 6 to 17 show the active layers and the metal layers of the display panel 10 layer by layer according to the film stacking sequence shown in FIG. 5, FIG. 13 shows the stacking of LTPO-related films, and FIG. 17 shows the stacking of FIAA-related films.

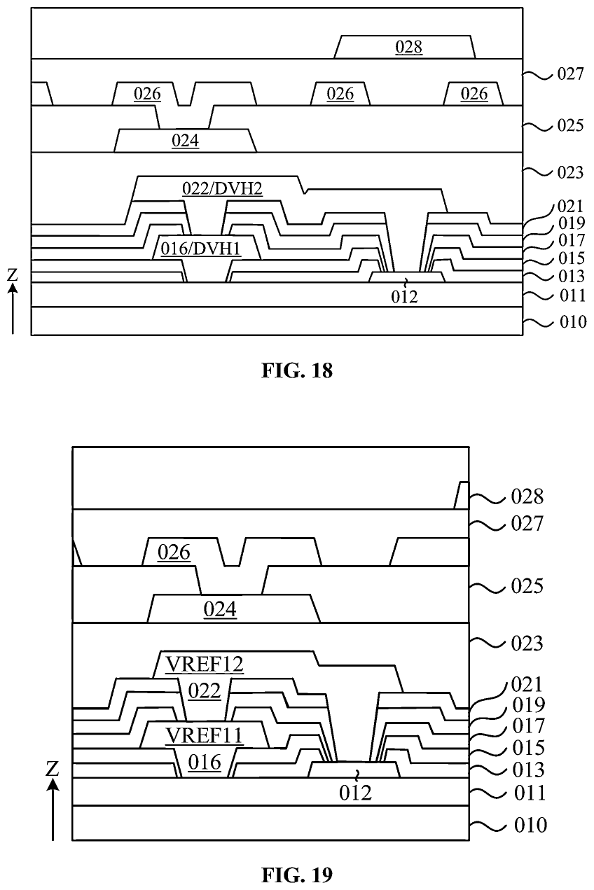

For example, FIG. 18 is a sectional view of FIG. 6 taken along A1A2, which shows an electrical connection between bias signal lines DVH in different films in the intersection manner. Referring to FIGS. 6, 13 and 18, the bias signal lines DVH may include the first bias signal sublines DVH1 and the second bias signal sublines DVH2 extending in different directions and electrically connected in the intersection manner, where the first bias signal sublines DVH1 extend along the first direction X and are arranged along the second direction Y, and the second bias signal sublines DVH2 extend along the second direction Y and are arranged along the first direction X; and the first bias signal subline DVH1 may be disposed in the capacitor metal layer 016, the second bias signal subline DVH2 may be disposed in the source-drain electrode layer 022, and a via is disposed at an intersection position of the second bias signal subline DVH2 and the first bias signal subline DVH1 to implement the electrical connection therebetween. In other embodiments, the bias signal lines DVH may be electrically connected in the intersection manner based on wires in another metal layer, which is not limited here.

In some embodiments, with continued reference to FIGS. 2 and 6, the pixel driving circuit 20 may further include the first reset transistor T7, and the signal lines 30 further include the first reset signal lines VREF1, where the first reset transistor T7 is electrically connected between the first reset signal line VREF1 and the light-emitting element 200, and the gate of the first reset transistor T7 is connected to the bias control signal line SP.

The first reset transistor T7 is configured to be selectively turned on under the control of the bias control signal provided by the bias control signal line SP. When the bias control signal line SP controls the first reset transistor T7 to be turned on, the first reset signal transmitted on the first reset signal line VREF1 is transmitted to the anode of the light-emitting element 200 to reset the fourth node N4, so as to avoid an effect of the previous frame on the display of a current frame and ensure relatively good consistency of the image display.

In some embodiments, with continued reference to FIG. 6, the first reset signal lines VREF1 include first reset signal sublines VREF11 extending along the first direction X and arranged along the second direction Y and second reset signal sublines VREF12 extending along the second direction Y and arranged along the first direction X, where the first reset signal sublines VREF11 and the second reset signal sublines VREF12 are electrically connected.

The first reset signal lines VREF1 include the first reset signal sublines VREF11 and the second reset signal sublines VREF12 extending in different directions and electrically connected in the intersection manner, where the first reset signal sublines VREF11 extend along the first direction X and are arranged along the second direction Y, and the second reset signal sublines VREF12 extend along the second direction Y and are arranged along the first direction X. A plurality of first reset signal sublines VREF11 and a plurality of second reset signal sublines VREF12 may be provided, where the plurality of first reset signal sublines VREF11 and the plurality of second reset signal sublines VREF12 may intersect at a plurality of positions. The first reset signal sublines VREF11 and the second reset signal sublines VREF12 may be electrically connected at all the intersection positions, or the first reset signal sublines VREF11 and the second reset signal sublines VREF12 may be electrically connected at part of the intersection positions. Specifically, each first reset signal subline VREF11 may be connected to at least one second reset signal subline VREF12, and each second reset signal subline VREF12 may be connected to at least one first reset signal subline VREF11.

In the display panel 10 according to the embodiments of the present disclosure, the first reset signal lines VREF1 include the first reset signal sublines VREF11 and the second reset signal sublines VREF12 extending in different directions and electrically connected in the intersection manner so that the overall size of the first reset signal lines VREF1 can be increased, the overall resistance of the first reset signal lines VREF1 can be reduced, and the first reset signal lines VREF1 are less susceptible to the coupling interference of other signal lines 30. In this manner, first reset signals at different positions of the display panel 10 have relatively good consistency, thereby improving the consistency of grayscales and facilitating the improvement of the quality of image display of the display panel 10. For example, the problem of the display split screen at the position of the opening in the display region can be alleviated.

In some embodiments, FIG. 19 is a sectional view of FIG. 6 taken along B1B2, which shows an electrical connection between first reset signal lines VREF1 in different films in the intersection manner. Referring to FIGS. 6, 13 and 19, the first reset signal lines VREF1 may include the first reset signal sublines VREF11 and the second reset signal sublines VREF12 extending in different directions and electrically connected in the intersection manner, where the first reset signal sublines VREF11 extend along the first direction X and are arranged along the second direction Y, and the second reset signal sublines VREF12 extend along the second direction Y and are arranged along the first direction X; and the first reset signal subline VREF11 may be disposed in the capacitor metal layer 016, the second reset signal subline VREF12 may be disposed in the source-drain electrode layer 022, and a via is disposed at an intersection position of the second reset signal subline VREF12 and the first reset signal subline VREF11 to implement the electrical connection therebetween. In other embodiments, the first reset signal lines VREF1 may be electrically connected in the intersection manner based on wires in another metal layer, which is not limited here.

In some embodiments, referring to FIG. 18, the first bias signal subline DVH1 is arranged in a different layer from the second bias signal subline DVH2; referring to FIG. 19, the first reset signal subline VREF11 is arranged in a different layer from the second reset signal subline VREF12.

The first bias signal subline DVH1 and the second bias signal subline DVH2 are two signal lines constituting the bias signal lines DVH and extending in different directions, and the two signal lines extending in different directions are arranged in different layers, that is, the first bias signal subline DVH1 and the second bias signal subline DVH2 are disposed in different films separately, thereby facilitating the reduction of an arrangement difficulty of the signal lines.

For example, in conjunction with FIG. 6 or 13, the first bias signal subline DVH1 may be disposed in the capacitor metal layer, and the second bias signal subline DVH2 may be disposed in the source-drain electrode layer. In other embodiments, the first bias signal subline DVH1 and the second bias signal subline DVH2 may be arranged in another two different metal layers, for example, the first bias signal subline DVH1 is disposed in the capacitor metal layer, and the second bias signal subline DVH2 is disposed in the second gate metal layer, which is not limited here.

Similarly, the first reset signal subline VREF11 and the second reset signal subline VREF12 are two signal lines constituting the first reset signal lines VREF1 and extending in different directions, and the two signal lines extending in different directions are arranged in different layers, that is, the first reset signal subline VREF11 and the second reset signal subline VREF12 are disposed in different films separately, thereby facilitating the reduction of the arrangement difficulty of the signal lines.

For example, in conjunction with FIG. 6 or 13, the first reset signal subline VREF11 may be disposed in the capacitor metal layer, and the second reset signal subline VREF12 may be disposed in the source-drain electrode layer. In other embodiments, the first reset signal subline VREF11 and the second reset signal subline VREF12 may be arranged in another two different metal layers, for example, the first reset signal subline VREF11 is disposed in the capacitor metal layer, and the second reset signal subline VREF12 is disposed in the second gate metal layer, which is not limited here.

In the display panel 10 according to the embodiments of the present disclosure, the two signal lines constituting the bias signal lines DVH and extending in different directions are disposed in different films separately, and the two signal lines constituting the first reset signal lines VREF1 and extending in different directions are disposed in different films separately, thereby facilitating the reduction of the arrangement difficulty of the signal lines.

In some embodiments, the first reset signal lines VREF1 and the bias signal lines DVH are at least partially arranged in the same layer and insulated from each other.

The first reset signal lines VREF1 and the bias signal lines DVH each include the signal lines extending along the first direction X and the second direction Y Based on this, signal lines among the first reset signal lines VREF1 and the bias signal lines DVH and extending along the same direction of at least one direction may be arranged in the same layer and electrically insulated from each other. For example, signal lines extending along the first direction X are arranged in the same layer, for example, the first bias signal subline DVH1 and the first reset signal subline VREF11 are arranged in the same layer, and/or the second bias signal subline DVH2 and the second reset signal subline VREF12 are arranged in the same layer.

For example, in conjunction with the preceding description, among the first reset signal lines VREF1 and the bias signal lines DVH, the first reset signal subline VREF11 and the first bias signal subline DVH1 are both disposed in the capacitor metal layer, and the second reset signal subline VREF12 and the second bias signal subline DVH2 may both be disposed in the source-drain electrode layer. That is, the first reset signal lines VREF1 and the bias signal lines DVH are all arranged in the same layer and occupy two films. Alternatively, the first reset signal subline VREF11 may be disposed in the capacitor metal layer, the first bias signal subline DVH1 may be disposed in the second gate metal layer, and the second reset signal subline VREF12 and the second bias signal subline DVH2 may both be disposed in the source-drain electrode layer. That is, the first reset signal lines VREF1 and the bias signal lines DVH are partially arranged in the same layer and occupy three films.

In this embodiment, the first reset signal lines VREF1 and the bias signal lines DVH are at least partially arranged in the same layer and insulated from each other, thereby facilitating the reduction of a total number of metal layers occupied by the first reset signal lines VREF1 and the bias signal lines DVH and the design of a thin and light display panel. Moreover, two different types of signal line are formed in the same film, thereby facilitating an increase of a utilization rate of the film, improving wiring uniformity in the film, improving the uniformity of the electrical performance of the display panel 10, and improving the display effect.

In some embodiments, in conjunction with FIGS. 5 and 6, the display panel 10 includes a substrate 01, a first metal layer MC and a second metal layer M2, where the second metal layer M2 is disposed on a side of the first metal layer MC facing away from the substrate 01.

For example, the substrate 01 may include the substrate 010 and may further include the buffer layer 011, the first metal layer MC may be the capacitor metal layer 016, and the second metal layer M2 may be the source-drain electrode layer 022.

The first metal layer MC includes the first reset signal sublines VREF11 and the first bias signal sublines DVH1, that is, the capacitor metal layer 016 may include part of the first reset signal lines VREF1 and the bias signal sublines VREF1 extending along the first direction X, and the first reset signal sublines VREF11 are insulated from the first bias signal sublines DVH1 to transmit first reset signals and bias voltage signals, respectively.

The second metal layer M2 includes the second reset signal sublines VREF12 and the second bias signal sublines DVH2, that is, the source-drain electrode layer 022 may include part of the first reset signal lines VREF1 and the bias signal sublines DVH extending along the second direction Y, and the second reset signal sublines VREF12 are insulated from the second bias signal sublines DVH2 to transmit first reset signals and bias voltage signals, respectively.

In the embodiments of the present disclosure, the first metal layer MC includes the first reset signal sublines VREF11 and the first bias signal sublines DVH1, and the second metal layer M2 includes the second reset signal sublines VREF12 and the second bias signal sublines DVH2 so that the first reset signal lines VREF1 and the bias signal lines DVH are distributed in two metal layers, the same metal layer includes signal lines extending in the same direction, and signal lines extending in different directions are disposed in different metal layers, thereby reducing the wiring difficulty in the same metal layer and occupied films and facilitating the design of the thin and light display panel 10.

In some embodiments, with continued reference to FIG. 1 or 6, the pixel driving circuits 20 may be arranged in the array, for example, arranged in rows and columns, to drive the corresponding light-emitting elements to implement the image display.

In some embodiments, in conjunction with FIGS. 1, 6 and 9, the number of first reset signal sublines VREF11 is N11, the number of first bias signal sublines DVH1 is N12, and the number of rows of the pixel driving circuits 20 is N10, where N11≤N10, N12≤N10, and N10, N11 and N12 are positive integers.

With reference to the number of rows of the pixel driving circuits 20, the number of first reset signal sublines VREF11 may be equal to or less than the number of rows of the pixel driving circuits 20, and the number of first bias signal sublines DVH1 may also be equal to or less than the number of rows of the pixel driving circuits.

In some embodiments, both the first reset signal subline VREF11 and the first bias signal subline DVH1 may be provided for the same row of pixel driving circuits 20, and along the second direction Y, the first reset signal subline VREF11 and the first bias signal subline DVH1 may be disposed on an upper side and a lower side of the row of pixel driving circuits 20. In this case, N10=N11=N12 so that both the number of first reset signal sublines VREF11 and the number of first bias signal sublines DVH1 are increased, the overall size of the first reset signal lines VREF1 and the overall size of the bias signal lines DVH are increased, the overall resistance of the bias signal lines DVH and the overall resistance of the first reset signal lines VREF1 are reduced, and the bias voltage signals and the first reset signals have improved signal transmission stability, thereby reducing the coupling interference and improving the display effect of the display panel.

Alternatively, the first reset signal sublines VREF11 may be provided for pixel driving circuits 20 in some rows, and the first bias signal sublines DVH1 may be provided for pixel driving circuits 20 in other rows. In this case, N10>N11, and N10>N12 so that an arrangement density of the first reset signal sublines VREF11 and an arrangement density of the first bias signal sublines DVH1 are reduced to a certain extent, thereby reducing the arrangement difficulty of the signal lines while reducing the coupling interference and improving the display effect.

In some embodiments, along the second direction Y, the first reset signal sublines VREF11 and the first bias signal sublines DVH1 are alternately arranged, and N10≥N11+N12.

In this manner, the distribution uniformity of the first reset signal sublines VREF11 in the display panel and the distribution uniformity of the first bias signal sublines DVH1 in the display panel can be improved so that the wiring uniformity in the film is improved, thereby facilitating the improvement of the overall signal consistency of the display panel and improving the display effect.

The first reset signal sublines VREF11 and the first bias signal sublines DVH1 may be alternately arranged at a certain number ratio. For example, a single first reset signal subline VREF11 and a single first bias signal subline DVH1 are alternately arranged in sequence, and the number ratio may be 1:1. Alternatively, two first reset signal sublines VREF11 and a single first bias signal subline DVH1 are alternately arranged in sequence, and the number ratio may be 2:1. Alternatively, the first reset signal sublines VREF11 and the first bias signal sublines DVH1 are alternately arranged at another number ratio, which is not limited here.

For example, with FIGS. 6 and 9 as an example, one first reset signal subline VREF11 and one first bias signal subline DVH1 are provided for two adjacent rows of pixel driving circuits 20 separately, and the first reset signal subline VREF11 and the first bias signal subline DVH1 are alternately arranged in sequence and at intervals. In this case, N10=N11+N12.

In this manner, the first reset signal subline VREF11 and the first bias signal subline DVH1 are spaced by one row of pixel driving circuits 20 so that when the wiring uniformity of the first reset signal sublines VREF11 and the wiring uniformity of the first bias signal sublines DVH1 are improved, an interval between the first reset signal subline VREF11 and the first bias signal subline DVH1 is increased, and a mutual effect is reduced, thereby facilitating the improvement of the distribution consistency of the first reset signals in the display panel and the distribution consistency of the bias voltage signals in the display panel and the display effect.

In some embodiments, neither first reset signal sublines VREF11 nor first bias signal sublines DVH1 may be provided for some rows of pixel driving circuits 20, but signal lines for transmitting other signals are arranged. In this case, N10>N11+N12. In this manner, when the display effect is improved, the requirement for arranging signal lines with different functions in limited films can be satisfied.

In other embodiments, the first reset signal sublines VREF11 and the first bias signal sublines DVH1 may be arranged in other manners, which are not limited here.

In some embodiments, in conjunction with FIGS. 1, 6, 12 and 13, the number of second reset signal sublines VREF12 is N21, the number of second bias signal sublines DVH2 is N22, and the number of columns of the pixel driving circuits 20 is N20, where N21≤N20, N22≤N20, and N20, N21 and N22 are positive integers.

With reference to the number of columns of the pixel driving circuits 20, the number of second reset signal sublines VREF12 may be equal to or less than the number of columns of the pixel driving circuits 20, and the number of second bias signal sublines DVH2 may also be equal to or less than the number of columns of the pixel driving circuits.

In some embodiments, both the second reset signal subline VREF12 and the second bias signal subline DVH2 may be provided for the same column of pixel driving circuits 20, and along the first direction X, the second reset signal subline VREF12 and the second bias signal subline DVH2 may be disposed on a left side and a right side of the column of pixel driving circuits 20. In this case, N20=N21=N22 so that both the number of second reset signal sublines VREF12 and the number of second bias signal sublines DVH2 are increased, the overall size of the first reset signal lines VREF1 and the overall size of the bias signal lines DVH are increased, the overall resistance of the bias signal lines DVH and the overall resistance of the first reset signal lines VREF1 are reduced, and the bias voltage signals and the first reset signals have improved signal transmission stability, thereby reducing the coupling interference and improving the display effect of the display panel.

Alternatively, the second reset signal sublines VREF12 may be provided for pixel driving circuits 20 in some columns, and the second bias signal sublines DVH2 may be provided for pixel driving circuits 20 in other columns. In this case, N20>N21, and N20>N22 so that an arrangement density of the second reset signal sublines VREF12 and an arrangement density of the second bias signal sublines DVH2 are reduced to a certain extent, thereby reducing the arrangement difficulty of the signal lines while reducing the coupling interference and improving the display effect.

In some embodiments, along the first direction X, the second reset signal sublines VREF12 and the second bias signal sublines DVH2 are alternately arranged, and N20≥N21+N22.

In this manner, the distribution uniformity of the second reset signal sublines VREF12 in the display panel and the distribution uniformity of the second bias signal sublines DVH2 in the display panel can be improved so that the wiring uniformity in the film is improved, thereby facilitating the improvement of the overall signal consistency of the display panel and improving the display effect.

The second reset signal sublines VREF12 and the second bias signal sublines DVH2 may be alternately arranged at a certain number ratio. For example, a single second reset signal subline VREF12 and a single second bias signal subline DVH2 are alternately arranged in sequence, and the number ratio may be 1:1. Alternatively, two second reset signal sublines VREF12 and a single second bias signal subline DVH2 are alternately arranged in sequence, and the number ratio may be 2:1. Alternatively, the second reset signal sublines VREF12 and the second bias signal sublines DVH2 are alternately arranged at another number ratio, which is not limited here.

For example, with FIGS. 6 and 12 as an example, one second reset signal subline VREF12 and one second bias signal subline DVH2 are provided for two adjacent columns of pixel driving circuits 20 separately, and the second reset signal subline VREF12 and the second bias signal subline DVH2 are alternately arranged in sequence and at intervals. In this case, N20=N21+N22.

In this manner, the second reset signal subline VREF12 and the second bias signal subline DVH2 are spaced by one column of pixel driving circuits 20 so that when the wiring uniformity of the second reset signal sublines VREF12 and the wiring uniformity of the second bias signal sublines DVH2 are improved, an interval between the second reset signal subline VREF12 and the second bias signal subline DVH2 is increased, and a mutual effect is reduced, thereby facilitating the improvement of the distribution consistency of the first reset signals in the display panel and the distribution consistency of the bias voltage signals in the display panel and the display effect.

In some embodiments, neither second reset signal sublines VREF12 nor second bias signal sublines DVH2 may be provided for some columns of pixel driving circuits 20, but signal lines for transmitting other signals are arranged. In this case, N20>N21+N22. In this manner, when the display effect is improved, the requirement for arranging signal lines with different functions in limited films can be satisfied.

In other embodiments, the second reset signal sublines VREF12 and the second bias signal sublines DVH2 may be arranged in other manners, which are not limited here.

In some embodiments, with continued reference to FIGS. 12 and 13, the second reset signal subline VREF12 includes a body portion extending along the second direction Y, and the second bias signal subline DVH2 includes a body portion extending along the second direction Y; and in two adjacent columns of pixel driving circuits 20, the body portion of the second reset signal subline VREF12 and the body portion of the second bias signal subline DVH2 are symmetrically arranged along the second direction Y.

An axis of symmetry of the second reset signal subline VREF12 and the second bias signal subline DVH2 may be a dashed line along the second direction Y in the figure. For ease of description, the pixel driving circuits are substantially delimited by dashed lines along the first direction X and the second direction Y in the figure.

In the embodiments of the present disclosure, the body portion of the second reset signal subline VREF12 and the body portion of the second bias signal subline DVH2 are symmetrically arranged so that the wiring difficulty can be reduced by a symmetrical design.

In some embodiments, with continued reference to FIGS. 2 and 6, the pixel driving circuit 20 further includes the second reset transistor T5, and the signal lines 30 further include the second reset signal lines VREF2, where the second reset transistor T5 is electrically connected between the second reset signal line VREF2 and the gate of the drive transistor T3.

The signal lines 30 may further include the first scan signal lines S1, and the gate of the second reset transistor T5 is connected to the first scan signal line S1; and the second reset transistor T5 is configured to be selectively turned on under the control of the first scan signal provided by the first scan signal line S1.

The first scan signal may be one of scan signals and includes the enable level and the disable level, where the enable level may turn the second reset transistor T5 on, and the disable level may turn the second reset transistor T5 off. When the first scan signal line S1 controls the second reset transistor T5 to be turned on, the second reset signal transmitted on the second reset signal line VREF2 is transmitted to the gate of the drive transistor T3 to reset the first node N1, so as to ensure relatively good consistency of the image display.

In some embodiments, with continued reference to FIGS. 6 and 11, the second reset signal lines VREF2 extend along at least one of the first direction X or the second direction Y FIGS. 6 and 11 illustrate that the second reset signal lines VREF2 extend along the first direction X. In other embodiments, the second reset signal lines VREF2 may extend along the second direction Y Alternatively, the second reset signal lines VREF2 extend along the first direction X and the second direction Y separately and are electrically connected in the intersection manner, which may be set based on the requirements of the display panel 10 and is not limited here.

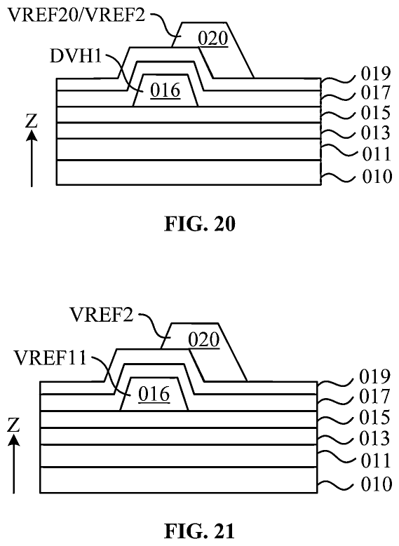

In some embodiments, FIG. 20 is a sectional view of FIG. 13 taken along A3A4. Referring to FIGS. 13 and 20, the second reset signal lines VREF2 include third reset signal sublines VREF20 extending along the first direction X, where the third reset signal sublines VREF20 are arranged in a different layer from the bias signal lines DVH.

For example, in conjunction with FIGS. 9, 11 and 12, the third reset signal sublines VREF20 may be disposed in the second gate metal layer 020/MG, and the bias signal lines DVH are disposed in the capacitor metal layer 016/MC and the source-drain electrode layer 022/M2.

In the embodiments of the present disclosure, the third reset signal sublines VREF20 are arranged in the different layer from the bias signal lines DVH so that intervals between the third reset signal sublines VREF20 and the bias signal lines DVH can be increased, thereby reducing signal coupling and improving the display effect.

In some embodiments, with continued reference to FIGS. 13 and 20, along a direction Z perpendicular to a plane where the substrate is located, the third reset signal sublines VREF20 at least partially overlap the first bias signal sublines DVH1. The direction Z perpendicular to the plane where the substrate is located is a thickness direction Z of the display panel 10, and the thickness direction Z is perpendicular to a plane determined by the first direction X and the second direction Y.

In this manner, a planar occupied area of the third reset signal sublines VREF20 and the first bias signal sublines DVH1 in the display panel 10 is reduced, thereby facilitating an increase of a space density of the signal lines, increasing a pixel density, and improving the display effect.

In some embodiments, FIG. 21 is a sectional view of FIG. 13 taken along B3B4. Referring to FIGS. 13 and 21, the third reset signal sublines VREF20 may also be arranged in a different layer from the first reset signal lines VREF1.

For example, in conjunction with FIGS. 9, 11 and 12, the third reset signal sublines VREF20 are disposed in the second gate metal layer, and the first reset signal lines VREF1 are disposed in the capacitor metal layer and the source-drain electrode layer.

In the embodiments of the present disclosure, the third reset signal sublines VREF20 are arranged in the different layer from the first reset signal lines VREF1 so that intervals between the third reset signal sublines VREF20 and the first reset signal lines VREF1 can be increased, thereby reducing the signal coupling and improving the display effect.

In some embodiments, with continued reference to FIGS. 13 and 21, along the direction Z perpendicular to the plane where the substrate is located, the third reset signal sublines VREF20 at least partially overlap the first reset signal lines VREF1.

In this manner, a planar occupied area of the third reset signal sublines VREF20 and the first reset signal lines VREF1 in the display panel 10 is reduced, thereby facilitating the increase of the space density of the signal lines, increasing the pixel density, and improving the display effect.

In some embodiments, with continued reference to FIGS. 11 and 13, the number of third reset signal sublines VREF20 is N13, and the number of rows of the pixel driving circuits 20 is N10, where N13≤N10, and N13 and N10 are positive integers.

For example, one third reset signal subline VREF20 may be provided for each row of pixel driving circuits 20, and N13=N10, that is, the ratio of the number of rows of the pixel driving circuits 20 to the number of third reset signal sublines VREF20 may be 1:1.

In other embodiments, the number of third reset signal sublines VREF20 may be less than the number of rows of the pixel driving circuits 20, that is, N13<N10. For example, every two rows of pixel driving circuits 20 correspond to one third reset signal subline VREF20, so as to reduce the number of third reset signal sublines VREF20, reduce the interference of signals transmitted on the third reset signal sublines VREF20 with other signal lines, and improve the display effect.

In the preceding embodiments, the bias signal lines DVH, the first reset signal lines VREF1 and the second reset signal lines VREF2 are illustrated. Other structures shown in FIGS. 5 to 21 are described below.

In conjunction with FIGS. 5, 6, 7 and 8, the polysilicon semiconductor layer includes a channel region p8 of the bias transistor T8, and along the direction perpendicular to the plane where the substrate is located, that is, the direction perpendicular to the plane formed by the first direction X and the second direction Y, the channel region p8 of the bias transistor T8 at least partially overlaps the bias control signal line SP. The channel region p8 of the bias transistor T8 is a region of the polysilicon semiconductor layer directly facing the bias control signal line SP, and an overlapping portion between the bias control signal line SP and the channel region p8 of the bias transistor T8 is the gate g8 of the bias transistor T8 so that the gate g8 of the bias transistor T8 is electrically connected to the bias control signal line SP.

In conjunction with FIGS. 5, 6, 7 and 18, the bias transistor T8 includes the channel region p8 in the polysilicon semiconductor layer and the first electrode p81 and the second electrode p82 connected to the channel region p8, the first electrode p81 of the bias transistor is electrically connected to the second bias signal subline DVH2 in the source-drain electrode layer, and the second bias signal subline DVH2 is electrically connected to the first bias signal subline DVH1 in the capacitor metal layer; and the second electrode p82 of the bias transistor T8 is connected to a second electrode p12 of the power write transistor T1 through a connecting portion K6 in the source-drain electrode layer and connected to the first electrode p31 of the drive transistor T3, that is, connected to the second node N2.

In conjunction with FIGS. 5, 6, 7 and 8, the polysilicon semiconductor layer includes a channel region p3 of the drive transistor T3, the gate g3 of the drive transistor T3 is disposed in the first gate metal layer, and in the direction perpendicular to the plane where the substrate is located, the gate g3 of the drive transistor T3 at least partially overlaps the channel region p3 of the drive transistor T3. The gate g3 of the drive transistor T3 is electrically connected to the compensation transistor T4 and the second reset transistor T5 through a first connecting portion K3 in the source-drain electrode layer.

The drive transistor T3 includes the channel region p3 in the polysilicon semiconductor layer and the first electrode p31 and the second electrode p32 connected to the channel region, and the second electrode p32 of the drive transistor T3 is connected to a first electrode p61 of the light emission control transistor T6.

It is to be noted that in FIGS. 7 and 10, portions of the transistors disposed in the polysilicon semiconductor layer are delimited. For example, FIG. 7 further shows an active region p1, a first electrode p11 and the second electrode p12 of the power write transistor, an active region p2, a first electrode p21 and a second electrode p22 of the data write transistor, an active region p6, the first electrode p61 and a second electrode p62 of the light emission control transistor and an active region p7, a first electrode p71 and a second electrode p72 of the first reset transistor, and FIG. 10 further shows an active region p4, a first electrode p41 and a second electrode p42 of the compensation transistor and an active region p5, a first electrode p51 and a second electrode p52 of the second reset transistor, which are not to limit specific regions. Different transistors may be electrically connected through connecting portions in a metal layer so that the gate, the first electrode and the second electrode of different transistors may correspond to the same node and have the same potential.

Different names and reference numerals are given in the figures only for a better explanation of the embodiments of the present disclosure.

It is to be noted that in FIGS. 8, 9 and 11, portions of the transistors disposed in the first gate metal layer, the capacitor metal layer and the second gate metal layer are delimited, such as a gate g1, a gate g2, a gate g4, a gate g5, a gate g6 and a gate g7, FIGS. 8 and 9 show a first plate Cst1 and a second plate Cst2 of the storage capacitor Cst, and FIG. 9 shows the structures for connections in the intersection manner and non-connections in the intersection manner for the bias signal lines DVH and the first reset signal lines VREF1. The following description is provided in conjunction with FIGS. 9, 12, 13, 18 and 19.

For example, the capacitor metal layer shown in FIG. 9 includes the first bias signal subline DVH1 and the first reset signal subline VREF11 extending along the first direction X, a connecting portion Z16 and a dummy portion Z06 electrically connected to the first bias signal subline DVH1 and a connecting portion Z15 and a dummy portion Z05 electrically connected to the first reset signal subline VREF11; and the source-drain electrode layer shown in FIG. 12 includes the second bias signal subline DVH2 and the second reset signal subline VREF12 extending along the second direction Y, a connecting portion Z24 and a dummy portion Z07 electrically connected to the second bias signal subline DVH2 and a connecting portion Z23 and a dummy portion Z08 electrically connected to the second reset signal subline VREF12; where the dummy portion Z05 and the dummy portion Z07 may overlap in the thickness direction Z of the display panel and are not electrically connected to each other, and the dummy portion Z06 and the dummy portion Z08 may overlap in the thickness direction Z of the display panel and are not electrically connected to each other; the connecting portion Z15 and the connecting portion Z23 may overlap in the thickness direction Z of the display panel and are electrically connected to each other so that the first reset signal subline VREF11 and the second reset signal subline VREF12 are electrically connected in the intersection manner; and the connecting portion Z16 and the connecting portion Z24 may overlap in the thickness direction Z of the display panel and are electrically connected to each other so that the first bias signal subline DVH1 and the second bias signal subline DVH2 are electrically connected in the intersection manner.

In some embodiments, the first power line PVDD in the display panel may be disposed in the capacitor metal layer and the first auxiliary metal layer, and the first power line PVDD in the capacitor metal layer and the first power line PVDD in the first auxiliary metal layer both extend along the first direction X and may be electrically connected through a connecting portion Z13 in the capacitor metal layer to transmit the first power signal. Since the first power lines PVDD are arranged in two different metal layers, the overall size of the first power lines PVDD is increased, and the overall resistance of the first power lines PVDD is reduced so that the coupling effect of other signals on the first power signal is reduced, thereby facilitating the enhancement of the stability of the first power signal and improving the display effect of the display panel.

In some embodiments, FIG. 12 also shows other connection/transition structures that may be included in the source-drain electrode layer. For example, a transition portion K1 represents a transition portion between the polysilicon semiconductor layer and an anode layer and may serve as a cushion layer to implement an electrical connection between the second electrode of the light emission control transistor T6 and the anode of the light-emitting element 200. Moreover, the transition portion K1 is disposed so that a via between the polysilicon semiconductor layer and the anode layer at this position is divided into two relatively shallow vias, thereby reducing a punching difficulty and improving the overall structural stability. For example, a transition portion K2 represents the transition between the drive transistor T3 and the compensation transistor T4 and specifically corresponds to the transition between the second electrode of the drive transistor T3 and the first electrode of the compensation transistor T4 so that the LTPS transistor (that is, the drive transistor T3) based on the polysilicon semiconductor layer and the IGZO transistor (that is, the compensation transistor T4) based on the oxide semiconductor layer are electrically connected. For example, a transition portion K5 represents a transition portion between the first power line PVDD in the first auxiliary metal layer and the first electrode of the power write transistor T1, and a position of the transition portion K5 may correspond to a position of the connecting portion Z13 in the capacitor metal layer, that is, the transition portion K5 at least partially overlaps the connecting portion Z13 in the thickness direction of the display panel so that the first power line PVDD is connected to the first electrode of the power write transistor T1. For example, a transition portion K7 represents a transition portion between the bias signal line DVH and the first electrode of the drive transistor T3 and is used for implementing an electrical connection between the bias signal line DVH and the first electrode of the drive transistor T3. For example, a transition portion K8 represents a transition portion between the data line DL in the second auxiliary metal layer and the data write transistor T2 and is used for implementing an electrical connection between the data line DL and the first electrode of the data write transistor T2. In other embodiments, the source-drain electrode layer may further include other structures, which are not limited here.

In some embodiments, FIGS. 14 to 17 show another patterned structures of the first auxiliary metal layer, the second auxiliary metal layer and the reflective electrode layer. For example, referring to FIGS. 14 to 17, signal lines extending along the first direction X and connection structures may be arranged in the first auxiliary metal layer, signal lines extending along the second direction Y and connection structures may be arranged in the second auxiliary metal layer, and the anode RE of the light-emitting element and connection structures may be arranged in the reflective electrode layer. For details, reference is made to the following description of the FIAA structure.

The structure of the display panel 10 according to the embodiments of the present disclosure is illustrated in the preceding embodiments. Other structures of the display panel 10 are shown below, where the structures of some films (for example, films other than the second gate metal layer, the capacitor metal layer and the source-drain electrode layers) may be the same as those described above and may be understood with reference to the above description, which are not repeated hereinafter.

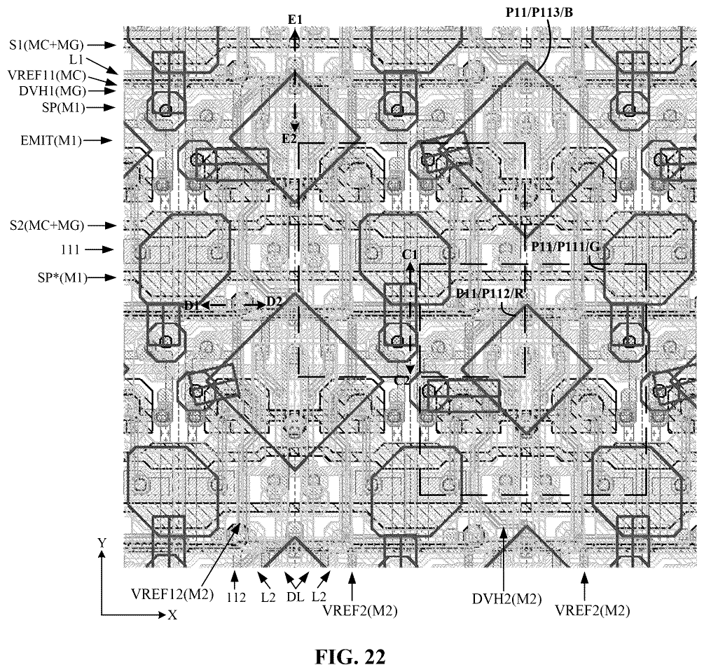

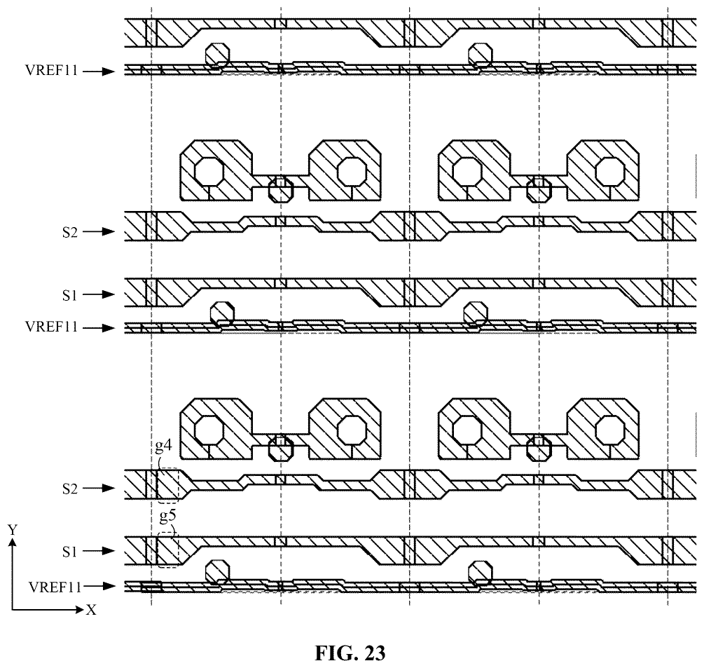

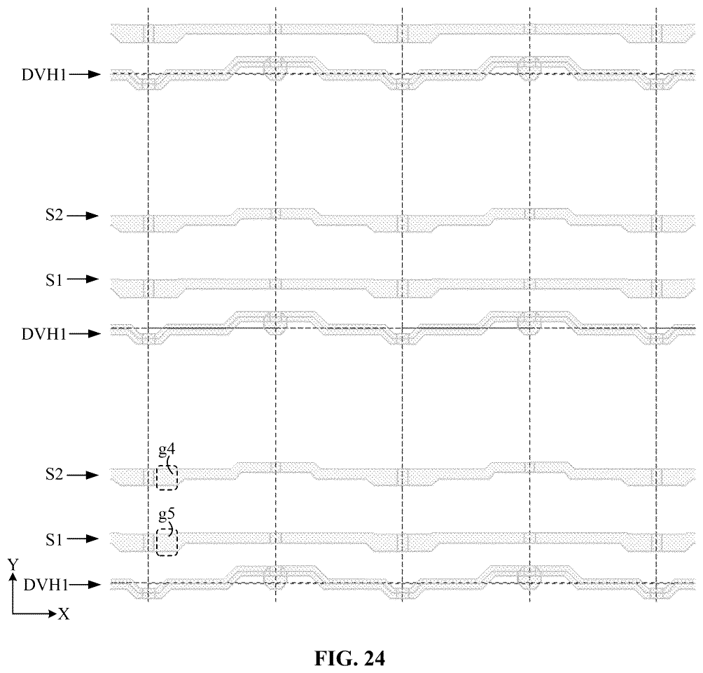

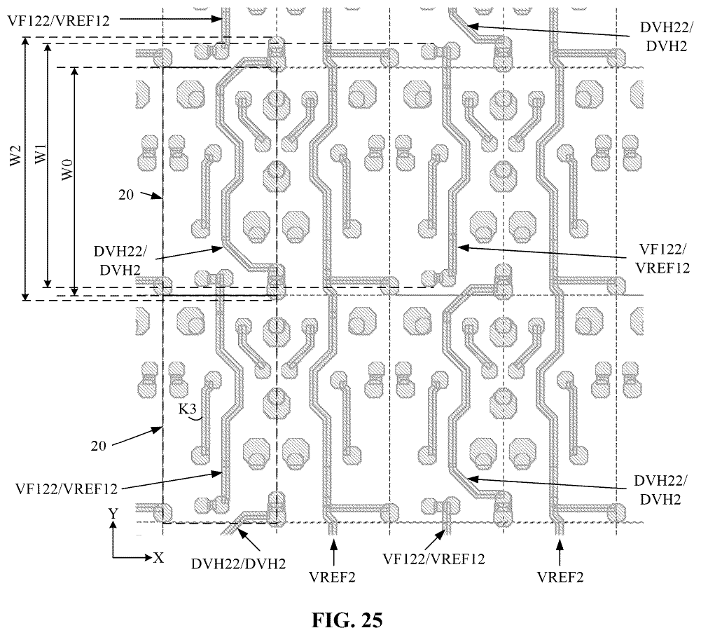

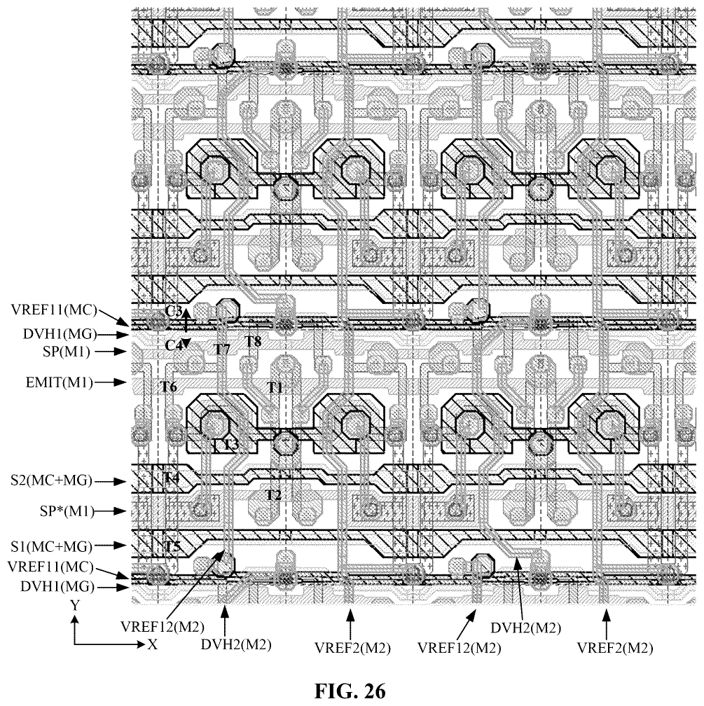

In some embodiments, FIG. 22 is a structure diagram of a partial layout of another display panel according to an embodiment of the present disclosure, FIG. 23 is a structure diagram of another capacitor metal layer according to an embodiment of the present disclosure, FIG. 24 is a structure diagram of another second gate metal layer according to an embodiment of the present disclosure, FIG. 25 is a structure diagram of another source-drain electrode layer according to an embodiment of the present disclosure, and FIG. 26 is another structure diagram of staked layers from a polysilicon semiconductor layer to a source-drain electrode layer according to an embodiment of the present disclosure. In this embodiment, the structures of other films in the display panel, such as the first active layer, the first gate metal layer, the second active layer, the first auxiliary metal layer, the second auxiliary metal layer and the reflective electrode layer, are the same as those described above and may be understood with reference to the above description, which are not repeated hereinafter.

In some embodiments, the display panel 10 includes the substrate 01, the first metal layer MC, a second metal layer M2 and a third metal layer MG, where the second metal layer M2 is disposed on the side of the first metal layer MC facing away from the substrate 01, and the third metal layer MG is disposed between the first metal layer MC and the second metal layer M2.

For example, as shown in FIG. 5, the substrate 01 may include the substrate 010 and may further include the buffer layer 011, the first metal layer MC may be the capacitor metal layer 016, the second metal layer M2 may be the source-drain electrode layer 022, and the third metal layer MG may be the second gate metal layer 020.

The first metal layer MC includes the first reset signal sublines VREF11, that is, the capacitor metal layer 016 may include the first reset signal sublines VREF11; the third metal layer MG includes the first bias signal sublines DVH1, that is, the second gate metal layer 020 may include the first bias signal sublines DVH1; the second metal layer M2 includes the second reset signal sublines VREF12 and the second bias signal sublines DVH2, that is, the source-drain electrode layer 022 may include the second reset signal sublines VREF12 and the second bias signal sublines DVH2; and the second reset signal sublines VREF12 are insulated from the second bias signal sublines DVH2 to transmit the first reset signals and the bias voltage signals, respectively.

Part of the bias signal lines DVH extending along the first direction X and part of the first reset signal lines VREF1 extending along the first direction X may be arranged in the second gate metal layer 020 and the capacitor metal layer 016, respectively, and part of the bias signal lines DVH extending along the second direction Y and part of the first reset signal lines VREF1 extending along the second direction Y are both arranged in the source-drain electrode layer 022. In this manner, different parts of signal lines of the bias signal lines DVH and the first reset signal lines VREF1 are arranged in three different metal layers so that the signal coupling between the bias signal lines DVH and the first reset signal lines VREF1 can be reduced, thereby improving the display effect.

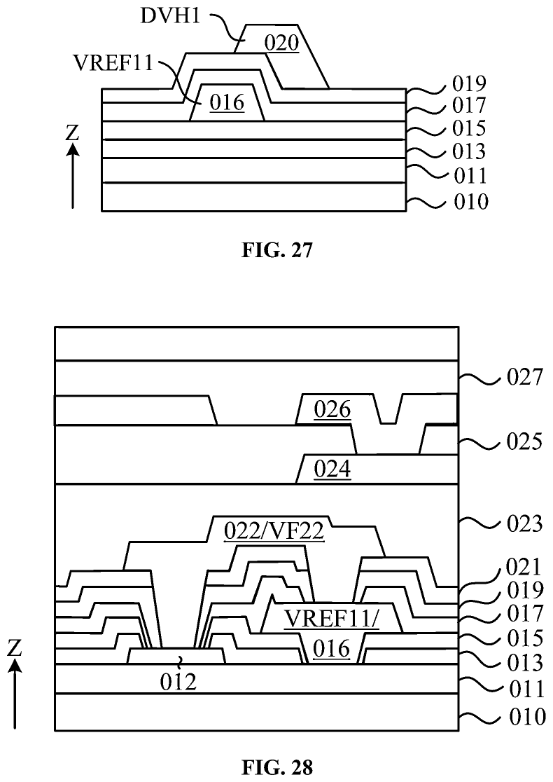

In some embodiments, FIG. 27 is a sectional view of FIG. 26 taken along C3C4. In conjunction with FIGS. 26 and 27, along the direction perpendicular to the plane where the substrate is located (that is, the thickness direction Z of the display panel 10), the first reset signal sublines VREF11 at least partially overlap the first bias signal sublines DVH1.

In this manner, a planar occupied area of the first reset signal sublines VREF11 and the first bias signal sublines DVH1 in the display panel 10 is reduced, thereby facilitating the increase of the space density of the signal lines, increasing the pixel density, and improving the display effect.

In some embodiments, as shown in FIGS. 22, 25 and 26, the second reset signal sublines VREF12 include a plurality of first sub-segments VF122 extending along the second direction Y and arranged along the second direction Y, where the plurality of first sub-segments VF122 are connected to the first reset signal sublines VREF11. Each first sub-segment VF122 herein may include a connecting portion connected to the first reset signal subline VREF11.

An occupied space of the pixel driving circuit 20 is shown by a dashed box in FIG. 25, where dashed lines along the first direction X and the second direction Y intersect to define dashed boxes, and each dashed box may represent the occupied space of one pixel driving circuit 20.

The first reset signal subline VREF11 may be continuous along the first direction X, and the second reset signal subline VREF12 may be intermittent along the second direction Y and connected to the first reset signal subline VREF11. The first reset signal subline VREF11 may be disposed between two adjacent rows of pixel driving circuits 20 along the first direction X. The second reset signal subline VREF12 includes a plurality of first sub-segments VF122 separated in the second direction Y, and each first sub-segment VF122 is connected to at least one first reset signal subline VREF11 overlapping the first sub-segment VF122 in the thickness direction of the display panel. For example, FIG. 28 is a sectional view of FIG. 22 taken along D1D2. In conjunction with FIGS. 22 and 28, the first sub-segment VF122 is connected to the first reset signal subline VREF11 through a via.

In some embodiments, as shown in FIGS. 22, 25 and 26, the second bias signal sublines DVH2 include a plurality of second sub-segments DVH22 extending along the second direction Y and arranged along the second direction Y, where each second sub-segment DVH22 spans at least one pixel driving circuit 20 along the second direction Y; and the plurality of second sub-segments DVH22 are connected to the first bias signal sublines DVH1. The second sub-segment DVH22 herein includes a connecting portion connected to the first reset signal subline VREF11.

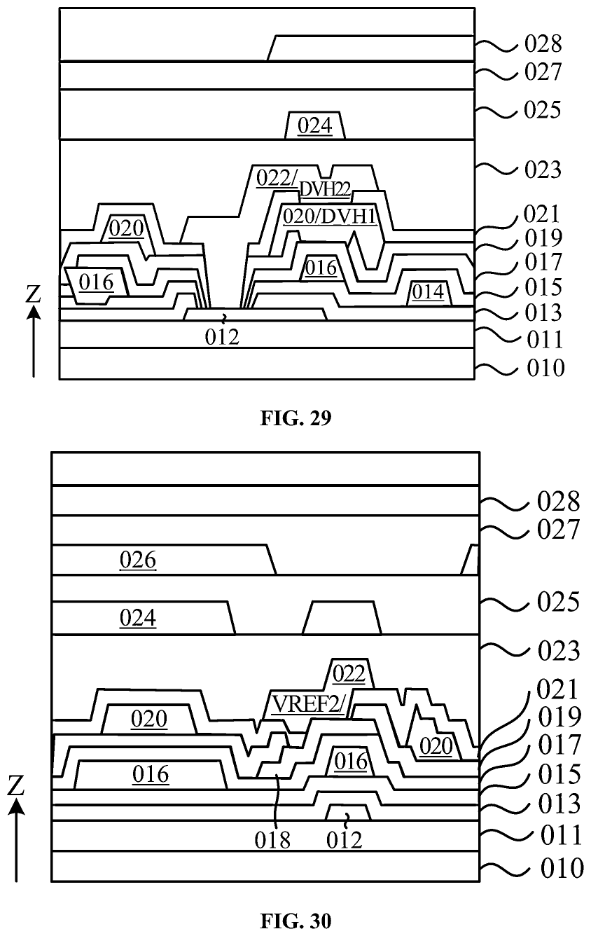

The first bias signal subline DVH1 may be continuous along the first direction X, and the second bias signal subline DVH2 may be intermittent along the second direction Y and connected to the first bias signal subline DVH1. The first bias signal subline DVH1 may be disposed between two adjacent rows of pixel driving circuits 20 along the first direction X and may cover the dashed line in the figure. The second bias signal subline DVH2 includes a plurality of second sub-segments DVH22 separated in the second direction Y, and each second sub-segment DVH22 is connected to at least one first bias signal subline DVH1 overlapping the second sub-segment DVH22 in the thickness direction of the display panel. For example, FIG. 29 is a sectional view of FIG. 22 taken along E1E2. In conjunction with FIGS. 22 and 29, the second sub-segment DVH22 is connected to the first bias signal subline DVH1 through a via.

In some embodiments, as shown in FIGS. 22, 25 and 26, the first sub-segment VF122 and the second sub-segment DVH22 are alternately arranged along the second direction Y.

The first sub-segment VF122 and the second sub-segment DVH22 may be alternately arranged at a certain number ratio along the second direction Y For example, a single first sub-segment VF122 and a single second sub-segment DVH22 are alternately arranged in sequence, and the number ratio may be 1:1. Alternatively, two first sub-segments VF122 and a single second sub-segment DVH22 are alternately arranged in sequence, and the number ratio may be 2:1. Alternatively, the first sub-segment VF122 and the second sub-segment DVH22 may be alternately arranged at another number ratio, which is not limited here.

In this manner, the wiring uniformity of the first sub-segments VF122 and the wiring uniformity of the second sub-segments DVH22 are improved, thereby improving the distribution consistency of the first reset signals and the bias voltage signals in the display panel and improving the display effect.

In some embodiments, with continued reference to FIG. 25, along the second direction Y, the length W1 of the first sub-segment VF122 is equal to or greater than the length W0 of the pixel driving circuit 20.

This setting facilitates an electrical connection between the first sub-segment VF122 and the first reset signal subline VREF11.

The length W0 of the pixel driving circuit 20 may be used for defining the distance between two dashed lines of the pixel driving circuit 20. The length of the first sub-segment VF122 may be understood as the linear length of the first sub-segment VF122 along the second direction Y or may be understood as a total length of wires of the first sub-segment VF122 including the bending of the signal line. The length of the first sub-segment VF122 is equal to or greater than the length W0 of the pixel driving circuit 20 so that the total length of wires of the first reset signal line VREF1 is increased, the overall size of the signal line is increased, and the resistance is reduced, thereby reducing signal coupling interference and improving the display effect.

In some embodiments, with continued reference to FIG. 25, the length W2 of the second sub-segment DVH22 is equal to or greater than the length W0 of the pixel driving circuit 20.

This setting facilitates an electrical connection between the second sub-segment DVH22 and the first bias signal subline DVH1.

The length W0 of the pixel driving circuit 20 may be used for defining the distance between two dashed lines of the pixel driving circuit 20. The length of the second sub-segment DVH22 may be understood as the linear length of the second sub-segment DVH22 along the second direction Y or may be understood as a total length of wires of the second sub-segment DVH22 including the bending of the signal line. The length of the sub-segment DVH22 is equal to or greater than the length W0 of the pixel driving circuit 20 so that the total length of wires of the bias signal line DVH is increased, the overall size of the signal line is increased, and the resistance is reduced, thereby reducing signal coupling interference and improving the display effect.

It is to be noted that FIGS. 22, 25 and 26 only illustrate that the first sub-segment VF122 and the second sub-segment DVH22 have substantially the same length as a single pixel driving circuit 20 along the second direction Y, which is not to limit the embodiments of the present disclosure. In other embodiments, the length of the first sub-segment VF122 and/or the second sub-segment DVH22 may be twice, three times or more times the length of the pixel driving circuit 20 along the second direction Y, which is not limited here.

In some embodiments, with continued reference to FIGS. 25 and 26, the number of pixel driving circuits 20 in the same column along the second direction Y is N30; among signal lines 30 in the same column and arranged along the second direction Y, the number of first sub-segments VF122 is N31, and the number of second sub-segments DVH22 is N32; where N30≥N31+N32, and N30, N31 and N32 are positive integers.

The first sub-segment VF122 and the second sub-segment DVH22 may be provided for pixel driving circuits 20 at different positions in the same column of pixel driving circuits 20. For example, as shown in FIG. 25 or 26, the first sub-segment VF122 and the second sub-segment DVH22 are provided for adjacent pixel driving circuits 20 in the second direction Y separately; and the first sub-segment VF122 and the second sub-segment DVH22 are spaced apart. That is, along the second direction Y, the first sub-segment VF122 and the second sub-segment DVH22 are alternately arranged in sequence and at intervals for the same column of pixel driving circuits 20, and the length of the first sub-segment VF122 and the length of the second sub-segment DVH22 are substantially the same as the length of the pixel driving circuit 20. In this case, N30=N31+N32. In this manner, the first sub-segments VF122 have relatively good distribution uniformity, and the second sub-segments DVH22 have relatively good distribution uniformity, facilitating the improvement of signal uniformity and improving the display effect.

In other embodiments, part of the pixel driving circuits 20 in the same column may be reserved, and for such pixel driving circuits 20, neither the first sub-segment VF122 nor the second sub-segment DVH22 may be provided, but signal lines for transmitting other signals are arranged. In this case, N30>N31+N32. In this manner, when the display effect is improved, the requirement for arranging signal lines with different functions in limited films can be satisfied.

In other embodiments, the first sub-segments VF122 and the second sub-segments DVH22 may be arranged in other manners, which are not limited here.

In some embodiments, in the source-drain electrode layer, the first sub-segment VF122 and the second sub-segment DVH22 are adjacent along the second direction Y and are connected to the first reset signal subline VREF11 in the capacitor metal layer and the first bias signal subline DVH1 in the second gate metal layer, respectively. To avoid the signal coupling between the first sub-segment VF122 and the second sub-segment DVH22, an end of at least one of the first sub-segment VF122 or the second sub-segment DVH22 may be bent so that the two signal lines are staggered and spaced apart, thereby reducing the signal coupling and improving the display effect.

In some embodiments, with continued reference to FIGS. 25 and 26, along the first direction X, the pixel driving circuits 20 are arranged in an array; and the first sub-segment VF122 and the second sub-segment DVH22 are at the same positions as the corresponding pixel driving circuits 20.

For example, the position of the pixel driving circuit 20 may be marked by a feature position such as a position of the first connecting portion K3 or a position of a via H1 on the second plate Cst2 of the storage capacitor Cst; relative to the pixel driving circuit 20, the first sub-segment VF122 and the second sub-segment DVH22 are bent towards the same side facing away from the first connecting portion K3 (or the via H1) in the first direction X and occupy the same spatial position.

In this manner, the first sub-segments VF122 and the second sub-segments DVH22 are wired regularly, thereby facilitating the reduction of the wiring difficulty.

In some embodiments, with continued reference to FIGS. 25 and 26, the first sub-segment VF122 and the second sub-segment DVH22 are alternately arranged along the first direction X.

The first sub-segment VF122 and the second sub-segment DVH22 may be alternately arranged at a certain number ratio along the first direction X. For example, a single first sub-segment VF122 and a single second sub-segment DVH22 are alternately arranged in sequence, and the number ratio may be 1:1. Alternatively, two first sub-segments VF122 and a single second sub-segment DVH22 are alternately arranged in sequence, and the number ratio may be 2:1. Alternatively, the first sub-segment VF122 and the second sub-segment DVH22 may be alternately arranged at another number ratio, which is not limited here.

In this manner, the wiring uniformity of the first sub-segments VF122 and the wiring uniformity of the second sub-segments DVH22 are improved, thereby improving the distribution consistency of the first reset signals and the bias voltage signals in the display panel and improving the display effect.

In some embodiments, in the same metal layer, the first sub-segment VF122 or the second sub-segment DVH22 may be provided for each pixel driving circuit 20 in the same row of pixel driving circuits 20 to make full use of the metal layer for wiring, thereby improving the utilization rate of the film and the wiring uniformity.

In other embodiments, part of the pixel driving circuits 20 in the same row may be reserved, and for such pixel driving circuits 20, neither the first sub-segment VF122 nor the second sub-segment DVH22 may be provided, but signal lines for transmitting other signals are arranged. In this manner, when the display effect is improved, the requirement for arranging signal lines with different functions in limited films can be satisfied.

For example, at least one column of pixel driving circuits 20 is disposed between the pixel driving circuit 20 corresponding to the first sub-segment VF122 and the pixel driving circuit 20 corresponding to the second sub-segment DVH22 adjacent to the first sub-segment VF122 along the first direction X.

For example, among three pixel driving circuits 20 adjacent to each other along the first direction X, the first sub-segment VF122 and the second sub-segment DVH 22 correspond to the first pixel driving circuit 20 and the last pixel driving circuit 20, respectively, and the middle pixel driving circuit 20 corresponds to neither the first sub-segment VF122 nor the second sub-segment DVH22. Alternatively, among three pixel driving circuits 20 adjacent to each other along the first direction X, the middle pixel driving circuit 20 corresponds to the first sub-segment VF122 or the second sub-segment DVH22, and the first and last pixel driving circuits 20 correspond to neither the first sub-segment VF122 nor the second sub-segment DVH22. In this manner, one column of pixel driving circuits 20 may be disposed between the pixel driving circuit 20 corresponding to the first sub-segment VF122 and the pixel driving circuit 20 corresponding to the second sub-segment DVH22 adjacent to the first sub-segment VF122 along the first direction X. In other embodiment, two columns, three columns or more columns of pixel driving circuits 20 may be disposed between the pixel driving circuit 20 corresponding to the first sub-segment VF122 and the pixel driving circuit 20 corresponding to the second sub-segment DVH22 adjacent to the first sub-segment VF122 along the first direction X, which is not limited here.

In the embodiments of the present disclosure, the first sub-segment VF122 and the second sub-segment DVH22 are both disposed in the source-drain electrode layer. With the preceding arrangement, the first sub-segment VF122 and the second sub-segment DVH22 in the source-drain electrode layer have a relatively large interval in the first direction X so that signal interference between the first sub-segment VF122 and the second sub-segment DVH22 is relatively small, thereby facilitating the accurate control of the first reset signals and the bias voltage signals related to the image display and the improvement of the image display effect.

In some embodiments, with continued reference to FIGS. 25 and 26, the second metal layer (that is, the source-drain electrode layer) may further include the second reset signal lines VREF2, and the second reset signal lines VREF2 extend along the second direction Y.

In this manner, signal lines arranged in the second metal layer all extend along the second direction Y, reducing the arrangement difficulty of the signal lines in the metal layer. Moreover, the second metal layer includes the first sub-segments VF122, the second sub-segments DVH22 and the second reset signal lines VREF2, which are not disposed in separate metal layers so that the wiring utilization rate and wiring uniformity of the second metal layer can be improved, thereby facilitating the improvement of signal uniformity and stability.

For example, FIG. 30 is a sectional view of FIG. 22 taken along C1C2, which shows a film structure of the second reset signal line VREF2 at a position of a via. Referring to FIG. 30 in conjunction with FIG. 10, the second reset signal line VREF2 in the source-drain electrode layer is connected through the via to the first electrode p51 of the second reset transistor T5 disposed in the oxide semiconductor layer 018.

In other embodiments, the second reset signal lines VREF2 may be disposed in at least one of the first metal layer (that is, the capacitor metal layer) or the third metal layer (that is, the second gate metal layer) and extend along the first direction X, which is not limited here.

In some embodiments, with continued reference to FIGS. 25 and 26, at least one second reset signal line VREF2 is disposed between the first sub-segment VF122 and the second sub-segment DVH22 adjacent to each other along the first direction X.

For example, one second reset signal line VREF2 may be disposed between the first sub-segment VF122 and the second sub-segment DVH22 adjacent to each other along the first direction X. In other embodiments, two or more second reset signal lines VREF2 may be disposed between the first sub-segment VF122 and the second sub-segment DVH22 adjacent to each other along the first direction X, or other signal lines may be disposed therebetween, which is not limited here.

In this manner, the second reset signal lines VREF2, the first reset signal lines VREF1 and the bias signal lines DVH in the entire display panel are balanced, thereby improving the overall stability of the second reset signals, the first reset signals and the bias voltage signals and improving the display effect of the display panel.

In some embodiments, with continued reference to FIGS. 25 and 26, the number of pixel driving circuits 20 in the same row is N40; among signal lines in the same row and arranged along the first direction X, the number of first sub-segments VF122 is N41, the number of second sub-segments DVH22 is N42, and the number of second reset signal lines VREF2 is N43; where N40≥N41+N42+N43, and N40, N41, N42 and N43 are positive integers.

The first sub-segment VF122, the second sub-segment DVH22 and the second reset signal line VREF2 may be provided for pixel driving circuits 20 at different positions in the same row of pixel driving circuits 20. For example, the second reset signal line VREF2 and the first sub-segment VF122 or the second reset signal line VREF2 and the second sub-segment DVH22 may be provided for two adjacent pixel driving circuits 20 along the first direction X, separately.

For example, as shown in FIG. 25 or 26, N40=N41+N42+N43. Specifically, for one row of pixel driving circuits 20 arranged along the first direction X, the second reset signal line VREF2, the first sub-segment VF122, the second reset signal line VREF2 and the second sub-segment DVH22 may be alternately arranged in sequence, and the signal line corresponding to the first pixel driving circuit 20 may be the second reset signal line VREF2, the first sub-segment VF122 or the second sub-segment DVH22, which is not limited here.

For example, as shown in FIG. 25 or 26, in an odd-numbered column, the first sub-segment VF122 and the second sub-segment DVH22 are alternately arranged in sequence and at intervals along the second direction Y, and in an even-numbered column, the second reset signal line VREF2 extends continuously along the second direction; and in the same row, the first sub-segment VF122 and the second sub-segment DVH22 are alternately arranged at intervals, and the second reset signal line VREF2 is disposed between the first sub-segment VF122 and the second sub-segment DVH22 adjacent to each other. Alternatively, in the even-numbered column, the first sub-segment VF122 and the second sub-segment DVH22 are alternately arranged in sequence and at intervals along the second direction Y, and in the odd-numbered column, the second reset signal line VREF2 extends continuously along the second direction; and in the same row, the first sub-segment VF122 and the second sub-segment DVH22 are alternately arranged at intervals, and the second reset signal line VREF2 is disposed between the first sub-segment VF122 and the second sub-segment DVH22 adjacent to each other.

For example, the second reset signal lines VREF2 are arranged only in the source-drain electrode layer, and the bias signal lines DVH and the first reset signal lines VREF1 are arranged in other metal layers than the source-drain electrode layer. The number ratio of the second reset signal lines VREF2, the first sub-segments VF122 and the second sub-segments DVH22 relative to the pixel driving circuits 20 is set such that the number of second reset signal lines VREF2 is greater than the number of first sub-segments VF122 in the same row, and the number of second reset signal lines VREF2 is greater than the number of second sub-segments DVH22 in the same row, facilitating the balance of the arrangement spaces of the second reset signal lines VREF2, the first reset signal lines VREF1 and the bias signal lines DVH in the entire display panel, making the resistance of the second reset signal lines VREF2, the resistance of the first reset signal lines VREF1 and the resistance of the bias signal lines DVH relatively small, reducing the coupling interference, improving the stability of the second reset signals, the first reset signals and the bias voltage signals, and improving the display effect of the display panel.

In other embodiments, part of the pixel driving circuits 20 in the same row may be reserved, and for such pixel driving circuits 20, none of the first sub-segment VF122, the second sub-segment DVH22 and the second reset signal line VREF2 may be provided, but signal lines for transmitting other signals are arranged. In this case, N40>N41+N42+N43. In this manner, when the display effect is improved, the requirement for arranging signal lines with different functions in limited films can be satisfied.

In some embodiments, with continued reference to FIGS. 25 and 26, the pixel driving circuit 20 further includes the first connecting portion K3 connected between the second reset transistor T5 and the gate of the drive transistor T3; along the first direction X, the first sub-segment VF122 and the second sub-segment DVH22 are disposed on a first side of the first connecting portion K3, and the second reset signal line VREF2 is disposed on a second side of the first connecting portion K3, where the first side and the second side are different sides of the first connecting portion K3. This facilitates the symmetrical design of the signal lines in the same metal layer, that is, the source-drain electrode layer, reducing the arrangement difficulty of the signal lines.

For example, with orientations shown in FIG. 25 as an example, the first sub-segment VF122 and the second sub-segment DVH22 are disposed on the right side of the first connecting portion K3, and the second reset signal line VREF2 is disposed on the left side of the first connecting portion K3.

In other embodiments, the first sub-segment VF122, the second sub-segment DVH22 and the second reset signal line VREF2 may be wired at other spatially relative positions, which is not limited here.

In some embodiments, with continued reference to FIG. 22, the display panel 10 further includes a plurality of sub-pixels P11 including a first color sub-pixel P111, a second color sub-pixel P112 and a third color sub-pixel P113.

Each sub-pixel P11 may include the pixel driving circuit 20 and the light-emitting element 200. Different color sub-pixels P11 may be distinguished based on different colors of light emitted by different light-emitting elements 200. Specifically, the light-emitting element 200 may include the anode, the light-emitting material layer 029 and a cathode; and the light-emitting element 200 may emit light of a different color based on different performance of the light-emitting material layer 029.

For example, a first color, a second color and a third color are different from each other so that the display panel 10 may present display effects based on different color combinations.

In some embodiments, the first color sub-pixel P111, the second color sub-pixel P112 and the third color sub-pixel P113 are each a red sub-pixel R, a green sub-pixel G or a blue sub-pixel B and are different from each other. In this manner, the display panel 10 can achieve full color display.

For example, the first color sub-pixel P111 may be the red sub-pixel R, the second color sub-pixel P112 may be the blue sub-pixel B, and the third color sub-pixel P113 may be the green sub-pixel G. FIG. 22 illustrates the arrangement and shapes of sub-pixels with the arrangement and shapes of anodes.

In other embodiments, the first color, the second color and the third color may be other colors, which is not limited here.

For example, with continued reference to FIG. 22, a plurality of first color sub-pixels P111 and a plurality of second color sub-pixels P112 constitute a first virtual quadrilateral, the center of the first color sub-pixel P111 is located at a first vertex of the first virtual quadrilateral, the center of the second color sub-pixel P112 is located at a second vertex of the first virtual quadrilateral, the first vertex and the second vertex are alternately spaced, and the third color sub-pixel P113 is located inside the first virtual quadrilateral; a plurality of third color sub-pixels P113 constitute a second virtual quadrilateral, the center of each of the plurality of third color sub-pixels P113 is located at a vertex of the second virtual quadrilateral, and the first color sub-pixel P111 or the second color sub-pixel P112 is located inside the second virtual quadrilateral. In this manner, a windmill arrangement is achieved so that when a relatively good display effect is achieved, high efficiency and energy saving can be achieved.

The second reset signal line VREF2 overlaps the pixel driving circuit 20 of the third color sub-pixel P113; and the first sub-segment VF122 and the second sub-segment DVH22 overlap the pixel driving circuit 20 of the first color sub-pixel P111 and the pixel driving circuit 20 of the second color sub-pixel P112 separately, where the sub-pixels are different. For example, the first sub-segment VF122 overlaps the pixel driving circuit 20 of the first color sub-pixel P111, and the second sub-segment DVH22 overlaps the pixel driving circuit of the second color sub-pixel P112; or the first sub-segment VF122 overlaps the pixel driving circuit of the second color sub-pixel P112, and the second sub-segment DVH22 overlaps the pixel driving circuit of the first color sub-pixel P111.

For example, the second reset signal line VREF2 overlaps the pixel driving circuit 20 of the green sub-pixel G, and the first sub-segment VF122 and the second sub-segment DVH 22 overlap the pixel driving circuit 20 of the red sub-pixel R and the pixel driving circuit 20 of the blue sub-pixel B separately, where the sub-pixels are different. Specifically, the first sub-segment VF122 overlaps the pixel driving circuit 20 of the red sub-pixel R, and the second sub-segment DVH22 overlaps the pixel driving circuit 20 of the blue sub-pixel B; or the first sub-segment VF122 overlaps the pixel driving circuit 20 of the blue sub-pixel B, and the second sub-segment DVH22 overlaps the pixel driving circuit 20 of the red sub-pixel R.

In the embodiments of the present disclosure, third color sub-pixels P113 (for example, green sub-pixels G) may be arranged along the second direction Y to form a pure color column; and the first color sub-pixel P111 and the second color sub-pixel P112 (for example, the red sub-pixel R and the blue sub-pixel B) may be arranged in sequence and at intervals along the second direction Y to form a mixed color column. Correspondingly, the second reset signal line VREF2 extending continuously may overlap the pixel driving circuits 20 of sub-pixels P11 in the pure color column; and the first sub-segment VF122 and the second sub-segment DVH22 arranged at intervals and extending segment by segment may overlap the pixel driving circuits 20 of sub-pixels P11 in the mixed color column, and the first sub-segment VF122 and the second sub-segment DVH22 may overlap the pixel driving circuits 20 of sub-pixels P11 of different colors, separately. In this manner, the signal lines may be arranged with reference to the arrangement rule of the sub-pixels, reducing the arrangement difficulty of the signal lines.

In other embodiments, a correspondence between the signal lines arranged and the sub-pixels arranged may be another relationship, which is not limited here.

In the embodiments of the present disclosure, FIGS. 5, 6 and 22 show the display panel that combines LTPO with FIAA, which is specifically described below.

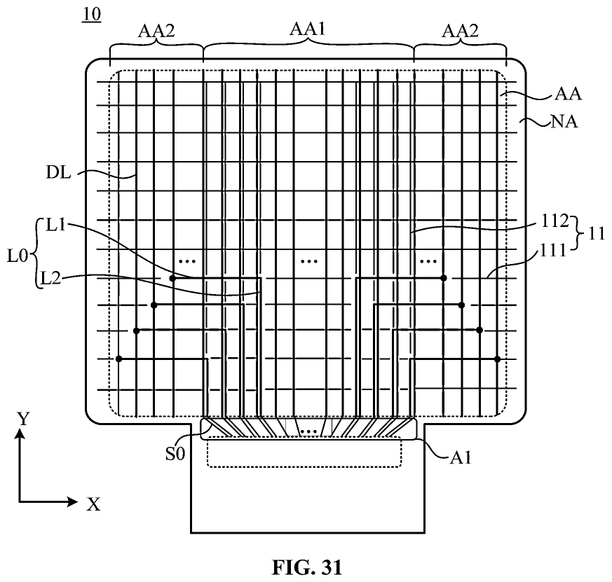

In some embodiments, FIG. 31 is a structure diagram of another display panel according to an embodiment of the present disclosure. Referring to FIG. 31, the display panel 10 includes a display region AA and a non-display region NA at least partially surrounding the display region AA; where the non-display region NA includes a fan-out region A1 located on a side of the display region AA along the second direction Y With orientations shown in FIG. 31 as an example, the fan-out region A1 is located on the lower side of the display region AA. The display region AA includes a first display region AA1 and a second display region AA2, where the second display region AA2 is located on at least one side of the first display region AA1 along the first direction X. With the orientations shown in FIG. 31 as an example, the second display region AA2 is located on the left side and the right side of the first display region AA1. In other embodiments, the second display region AA2 may be located on the left side or the right side of the first display region AA1, which is not limited here.

The display region AA is used for displaying an image and may include the sub-pixels arranged in an array, and the sub-pixel includes the pixel driving circuit and the light-emitting element to implement active light emission control and the image display. The non-display region NA at least partially surrounds the display region AA, for example, the non-display region NA may be disposed in at least part of a space on at least one side of the display region AA and is used for arranging peripheral circuits and wires to transmit signals for display to the display region AA, such as drive signals and power signals. The non-display region NA is not used for displaying the image and may also be referred to as a bezel region. The smaller the ratio of the non-display region NA to the planar area of the display panel 10, the higher the ratio of the display region AA and the easier a narrow bezel and a full screen are achieved.

The fan-out region A1 includes a plurality of fan-out wires S0, and the first display region AA1 and the second display region AA2 each include a plurality of data lines DL extending along the second direction Y and arranged along the first direction X; each of the plurality of data lines DL is connected to a respective one of the plurality of fan-out wires S0; where each data line DL in the second display region AA2 is connected to a respective fan-out wire S0 through a connection wire L0; and the connection wire L0 is disposed in the display region AA and includes a first connection wire segment L1 extending along the first direction X and a second connection wire segment L2 extending along the second direction Y, where the first connection wire segment L1 is electrically connected to the data line DL in the second display region AA2, and the second connection wire segment L2 is electrically connected to the fan-out wire S0.

With the structure shown in FIG. 31 as an example, the first display region AA1 may be located in the middle region of the display panel 10, and the second display region AA2 may be located on two sides of the first display region AA1 so that the display panel 10 can be designed to be symmetrical left and right, reducing the arrangement difficulty of the signal lines.

The data lines DL in the first display region AA1 are electrically connected to fan-out wires S0 distributed in the fan-out region A1 directly; and the data line DL in the second display region AA2 is electrically connected to the fan-out wire S0 in the fan-out region A1 through the connection wire L0 including the first connection wire segment L1 extending along the first direction X and the second connection wire segment L2 extending along the second direction Y In this manner, fan-out wires do not need to be arranged at the lower left bezel and/or the lower right bezel of the display panel 10 so that space is provided for the bezel of the display panel 10 and the display device to be compressed, thereby facilitating the design of the narrow bezel of the display panel 10 and the display device and facilitating the full screen.

In some embodiments, the display region AA further includes auxiliary lines 11; the auxiliary lines 11 include at least one of a first auxiliary line 111 extending along the first direction X or a second auxiliary line 112 extending along the second direction Y; and the first auxiliary line 111 is disposed in the same layer as the first connection wire segment L1 and insulated from the first connection wire segment L1 and the second connection wire segment L2; and the second auxiliary line 112 is disposed in the same layer as the second connection wire segment L2 and insulated from the first connection wire segment L1 and the second connection wire segment L2.

The auxiliary lines 11 are disposed in the display region AA and used for compensating for the non-uniformity of wires in the display region AA, thereby improving the wiring uniformity in the display region AA.

The auxiliary lines 11 and connection wires L0 may be at least partially arranged in the same layer and electrically insulated so that the auxiliary lines 11 are disposed in at least part of films where the connection wires L0 are located, thereby making full use of wires in the films and improving the arrangement uniformity of the wires in the films.

The auxiliary lines 11 may include the first auxiliary line 111 and the second auxiliary line 112 whose extension directions intersect. The first auxiliary line 111 and the first connection wire segment L1 are arranged in the same layer, may both extend along the first direction X, and may be electrically insulated through an interval between the first auxiliary line 111 and the first connection wire segment L1, and the first auxiliary line 111 is also electrically insulated from the second connection wire segment L2. The second auxiliary line 112 and the second connection wire segment L2 are arranged in the same layer, may both extend along the second direction Y, and may be electrically insulated through an interval between the second auxiliary line 112 and the second connection wire segment L2, and the second auxiliary line 112 is also electrically insulated from the first connection wire segment L1. The first auxiliary line 111 is disposed in the film where the first connection wire segment L1 is located, and/or the second auxiliary line 112 is disposed in the film where the second connection wire segment L2 is located, facilitating the improvement of uniformity of a wire density of the film where the first connection wire segment L1 and/or the second connection wire segment L2 are located, the improvement of display non-uniformity due to the non-uniformity of the wire density, and the improvement of display uniformity of the display panel 10.

It is to be noted that FIG. 31 illustrates only connection relationships between the data lines DL, the fan-out wires S0, the connection wires L0 and the auxiliary lines 11 included in the display panel, which are described above by way of example, and the number of data lines DL, the number of fan-out wires S0, the number of connection wires L0 and the number of auxiliary lines 11 actually included in the display panel 10 are not limited.

It is to be understood that FIG. 31 illustrates only the structure of a lower bezel included in the display panel 10, and the structure of an upper bezel may be any structure known to those skilled in the art, which is neither repeated nor limited here.

In some embodiments, the auxiliary lines 11 may be floated. Alternatively, the auxiliary lines 11 may serve as power signal lines for transmitting power signals. For example, the auxiliary lines 11 may be connected to the first power lines PVDD and used for transmitting first power signals; and/or the auxiliary lines 11 may be connected to the second power lines PVEE and used for transmitting second power signals so that voltage drops at different positions of the display panel can be balanced, thereby facilitating the improvement of display uniformity, which is not limited here.

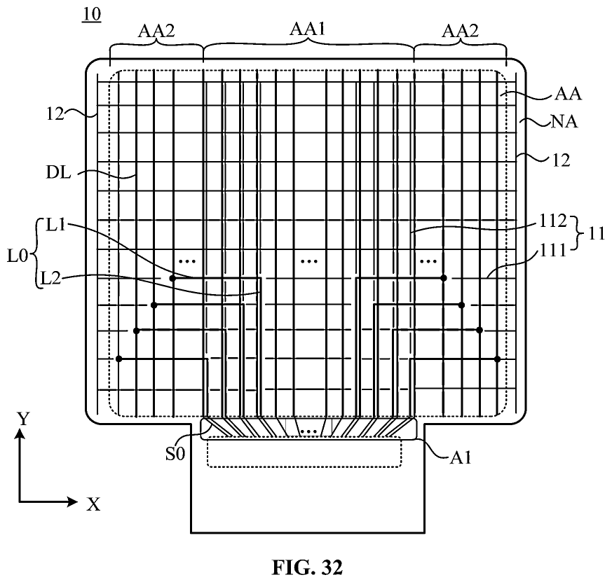

In some embodiments, FIG. 32 is a structure diagram of another display panel according to an embodiment of the present disclosure, and FIG. 33 is a structure diagram of another display panel according to an embodiment of the present disclosure. Referring to FIG. 32 or 33, the non-display region NA further includes power buses 12; and the auxiliary lines 11 are connected to the power buses 12 and may be used for transmitting corresponding power signals. For example, the power buses 12 may be disposed in the reflective electrode layer.

For example, as shown in FIG. 32, in the non-display region NA, the power buses 12 may each be a block or line structure. Alternatively, as shown in FIG. 33, in the non-display region NA, the power buses 12 may include a first bus 121 and a second bus 122 designed to be spaced apart and electrically connected; where a hollowed-out region exists between the first bus 121 and the second bus 122 and overlaps a pixel defining layer, so as to reduce an overlapping area between the reflective electrode layer and the pixel defining layer in the non-display region NA so that a capability of electrostatic discharge generated by the pixel defining layer to conduct downward along the overlapping portion decreases greatly, thereby reducing dark spots and improving the display effect and a product yield.

In some embodiments, first connection wire segments L1 of the connection wires L0 and first auxiliary lines 111 of the auxiliary lines 11 are arranged in the same layer, and the extension direction of the first auxiliary line 111 is the same as the extension direction of the first connection wire segment L1; and second connection wire segments L2 of the connection wires L0 and second auxiliary lines 112 of the auxiliary lines 11 are arranged in the same layer, and the extension direction of the second auxiliary line 112 is the same as the extension direction of the second connection wire segment L2, facilitating the improvement of uniformity of the wire density of the films where the first connection wire segment L1 and the second connection wire segment L2 are located and the improvement of display non-uniformity due to the non-uniformity of the wire density and improving the display uniformity of the display panel.

Meanwhile, the first connection wire segments L1 of all the connection wires L0 and the first auxiliary lines 111 of all the auxiliary lines 11 are arranged in the same layer, and the second connection wire segments L2 of all the connection wires L0 and the second auxiliary lines 112 of all the auxiliary lines 11 are arranged in another layer so that the first connection wire segments L1 and the first auxiliary lines 111 extending along the first direction X are arranged in one of two films, and the second connection wire segments L2 and the second auxiliary lines 112 extending along the second direction Y are arranged in the other film. The wires in a single film have the same extension direction, thereby simplifying the patterning of the single film, reducing the technique difficulty, and facilitating the improvement of the yield.

In some embodiments, the display panel further includes the substrate, the first metal layer, the second metal layer, the third metal layer, a fourth metal layer and a fifth metal layer, where the second metal layer is disposed on the side of the first metal layer facing away from the substrate, the third metal layer is disposed between the first metal layer and the second metal layer, the fourth metal layer is disposed on a side of the second metal layer facing away from the first metal layer, and the fifth metal layer is disposed on a side of the fourth metal layer facing away from the second metal layer.

For example, in conjunction with FIGS. 5 to 30, the first metal layer may be the capacitor metal layer, the second metal layer may be the source-drain electrode layer, the third metal layer may be the second gate metal layer, the fourth metal layer may be the first auxiliary metal layer, and the fifth metal layer may be the second auxiliary metal layer.

The first metal layer and the second metal layer include the bias signal lines; or the second metal layer and the third metal layer include the bias signal lines; the fourth metal layer includes the first auxiliary line and the first connection wire segment; and the fifth metal layer includes the second auxiliary line and the second connection wire segment.

That is, the bias signal lines may be distributed in the first metal layer and the second metal layer or distributed in the second metal layer and the third metal layer. The first auxiliary line and the second auxiliary line of the auxiliary lines may be distributed in the fourth metal layer and the fifth metal layer, and the first connection wire segment and the second connection wire segment of the connection wire may be distributed in the fourth metal layer and the fifth metal layer.

For example, in conjunction with the preceding description, the first auxiliary metal layer is used for arranging signal lines extending along the first direction X, and the second auxiliary metal layer is used for arranging signal lines extending along the second direction Y; and connecting/transition portions are disposed in both the fourth metal layer and the fifth metal layer to implement electrical connections between different signal lines and/or different circuit devices.

Specifically, as shown in FIG. 14, the first auxiliary metal layer may include the first connection wire segment L1 and the first auxiliary line 111 extending along the first direction X and connecting portions shown as Z31, Z32, Z33, Z34 and Z35 separately; as shown in FIG. 15, the second auxiliary metal layer may include the second connection wire segment L2 and the second auxiliary line 112 extending along the second direction Y and connecting portions shown as Z41, Z42 and Z43 separately. In some embodiments, the data lines DL may also be arranged in the second auxiliary metal layer and/or the first auxiliary metal layer, which is not limited here.

The connecting portion Z31 and the connecting portion Z41 at least partially overlap and are electrically connected through a via so that the first connection wire segment L1 and the second connection wire segment L2 are electrically connected; and the connecting portion Z32 and the connecting portion Z42 at least partially overlap and are electrically connected through a via so that the first auxiliary line 111 and the second auxiliary line 112 are electrically connected.

The connecting portion Z34 in FIG. 14 and the connecting portion Z43 in FIG. 15 each serve as a cushion metal and may at least partially overlap and be electrically connected to the transition portion K1 in the source-drain electrode layer so that a transistor (for example, the light emission control transistor T6) and the anode are electrically connected.

The auxiliary lines 11 may be used for transmitting the first power signals. In this case, the connecting portion Z33 in FIG. 14 is connected to the first power line in another film (for example, the capacitor metal layer); and the connecting portion Z35 is electrically connected to the first electrode of the power write transistor T1 through a downward via.

In some embodiments, the display region AA further includes at least one of the first power lines PVDD or the data lines DL, where the first power line PVDD is connected to the gate of the drive transistor T3; and at least one of the fourth metal layer or the fifth metal layer includes the first power lines PVDD, and the first power line PVDD is electrically insulated from the connection wire L0.

In some embodiments, the fifth metal layer includes the data lines DL.

In the embodiments of the present disclosure, besides the auxiliary lines 11 and the connection wires L0, at least one of the first power lines PVDD or the data lines DL may be arranged in the fourth metal layer and the fifth metal layer. For example, the auxiliary lines 11 may serve as the first power lines PVDD. FIG. 15 shows that the data lines DL are arranged in the fifth metal layer. Thus, the fourth metal layer and the fifth metal layer can be fully utilized, and the wiring uniformity can be improved.

In other embodiments, other signal lines may be arranged in the fourth metal layer and/or the fifth metal layer, which is not limited here.

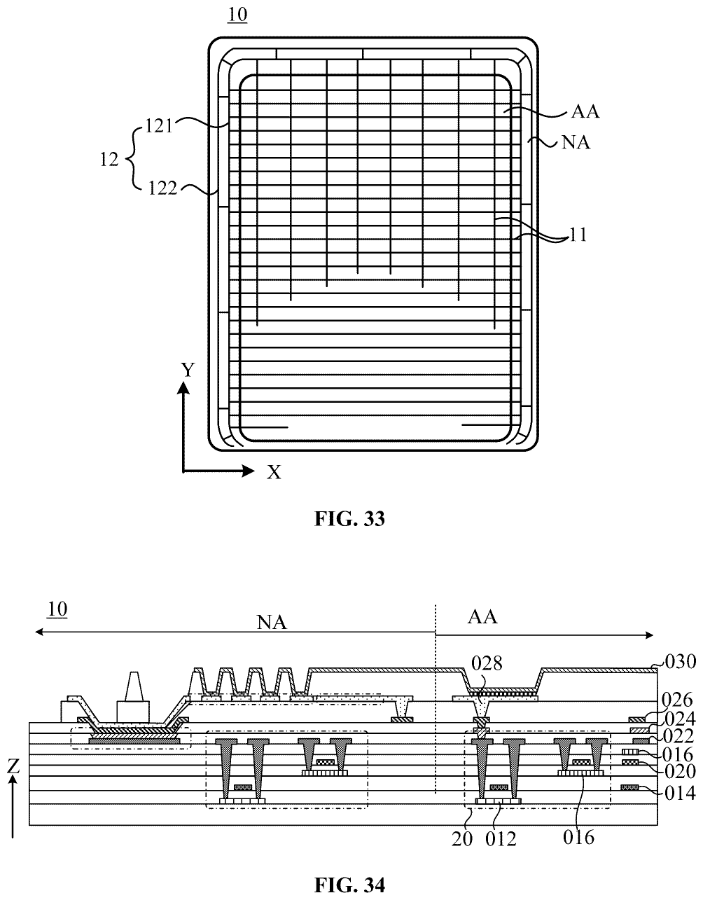

In some embodiments, FIG. 34 is a sectional view of another display panel according to an embodiment of the present disclosure. Referring to FIG. 34, the plurality of transistors in the pixel driving circuit 20 may include oxide transistors and LTPS transistors.

For example, in conjunction with FIG. 6 or 22, in the pixel driving circuit 20, the compensation transistor T4 and the second reset transistor T5 may be IGZO transistors to reduce a leakage current; and the drive transistor T3, the bias transistor T8, the first reset transistor T7, the power write transistor T1, the data write transistor T2 and the light emission control transistor T6 may be LTPS transistors.

In other embodiments, the structure of the pixel driving circuit 20 and the types of the transistors may be other combinations, which are not limited here.

Based on the preceding embodiments, the embodiments of the present disclosure further provide a display device.

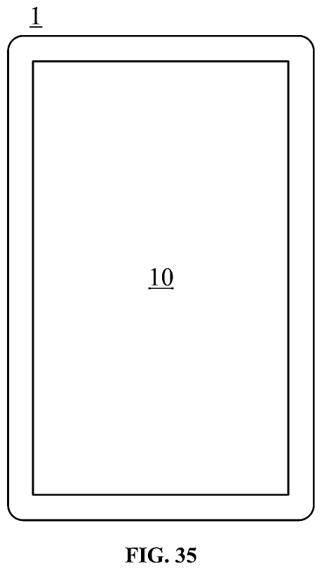

For example, FIG. 35 is a structure diagram of a display device according to an embodiment of the present disclosure. As shown in FIG. 35, a display device 1 may include any one of the display panels 10 according to the preceding embodiments and has the corresponding beneficial effects. To avoid a repeated description, the details are not repeated here.

For example, the display device includes, but is not limited to, a mobile phone, a tablet computer, an in-vehicle computer, a smart wearable device having a display function and another structural component having a display function, which is neither repeated nor limited here.

It is to be noted that relational terms such as “first” and “second” used herein are used for distinguishing one entity or operation from another and are not necessarily used to require or imply any such actual relationship or order between these entities or operations. Moreover, terms “comprising” and “including” or any other variants thereof are intended to encompass a non-exclusive inclusion so that a process, method, article or device that includes a series of elements not only includes these elements but also includes other elements that are not expressly listed or are inherent to such process, method, article or device. In the absence of more restrictions, the elements defined by the statement “including a . . . ” do not exclude the presence of additional identical elements in the process, method, article or device that includes the elements.

The preceding are embodiments of the present disclosure to enable those skilled in the art to understand or implement the present disclosure. Various modifications made to these embodiments are apparent to those skilled in the art, and the general principles defined herein may be implemented in other embodiments without departing from the spirit or scope of the present disclosure. Therefore, the present disclosure is not limited to the embodiments described herein but is to accord with the widest scope consistent with the principles and novel features disclosed herein.

What is claimed is:

1. A display panel, comprising pixel driving circuits and signal lines, wherein
a pixel driving circuit of the pixel driving circuits comprises a drive transistor and a bias transistor, and the signal lines comprise bias signal lines;
the drive transistor comprises a gate, a first electrode and a second electrode; and the bias transistor is electrically connected between a bias signal line of the bias signal lines and at least one of the first electrode or the second electrode of the drive transistor; and
the bias signal lines comprise first bias signal sublines extending along a first direction and arranged along a second direction and second bias signal sublines extending along the second direction and arranged along the first direction, wherein the first direction intersects the second direction, and the first bias signal sublines and the second bias signal sublines are electrically connected.

2. The display panel of claim 1, wherein the pixel driving circuit further comprises a first reset transistor and a light-emitting element, and the signal lines further comprise first reset signal lines, wherein the first reset transistor is electrically connected between a first reset signal line of the first reset signal lines and the light-emitting element; and
the first reset signal lines comprise first reset signal sublines and second reset signal sublines, wherein the first reset signal sublines extend along the first direction and arranged along the second direction, the second reset signal sublines extend along the second direction and arranged along the first direction, and the first reset signal sublines and the second reset signal sublines are electrically connected.

3. The display panel of claim 2, wherein the first bias signal sublines are arranged in a different layer from the second bias signal sublines, and the first reset signal sublines are arranged in a different layer from the second reset signal sublines.

4. The display panel of claim 3, wherein the first reset signal lines and the bias signal lines are at least partially arranged in a same layer and insulated from each other.

5. The display panel of claim 3, wherein the display panel comprises a substrate, a first metal layer and a second metal layer, wherein the second metal layer is disposed on a side of the first metal layer facing away from the substrate;
the first metal layer comprises the first reset signal sublines and the first bias signal sublines, and the first reset signal sublines are insulated from the first bias signal sublines; and
the second metal layer comprises the second reset signal sublines and the second bias signal sublines, and the second reset signal sublines are insulated from the second bias signal sublines.

6. The display panel of claim 5, wherein the pixel driving circuits are arranged in an array; and
a number of the first reset signal sublines is N11, a number of the first bias signal sublines is N12, and a number of rows of the pixel driving circuits is N10, wherein N11≤N10, N12≤N10, and N10, N11 and N12 are positive integers,
wherein along the second direction, the first reset signal sublines and the first bias signal sublines are alternately arranged, and N10≥N11+N12.

7. The display panel of claim 5, wherein the pixel driving circuits are arranged in an array; and
a number of the second reset signal sublines is N21, a number of the second bias signal sublines is N22, and a number of columns of the pixel driving circuits is N20, wherein N21≤N20, N22≤N20, and N20, N21 and N22 are positive integers,
wherein along the first direction, the second reset signal sublines and the second bias signal sublines are alternately arranged, and N20≥N21+N22.

8. The display panel of claim 5, wherein the pixel driving circuit further comprises a second reset transistor, and the signal lines further comprise second reset signal lines, wherein the second reset transistor is electrically connected between a second reset signal line of the second reset signal lines and the gate of the drive transistor; and
the second reset signal lines extend along at least one of the first direction or the second direction.

9. The display panel of claim 8, wherein the second reset signal lines comprise third reset signal sublines extending along the first direction, wherein the third reset signal sublines are arranged in a different layer from the bias signal lines.

10. The display panel of claim 9, wherein along a direction perpendicular to a plane where the substrate is located, the third reset signal sublines at least partially overlap the first bias signal sublines.

11. The display panel of claim 9, wherein the pixel driving circuits are arranged in an array; and
a number of third reset signal sublines is N13, and a number of rows of the pixel driving circuits is N10, wherein N13≤N10, and N13 and N10 are positive integers.

12. The display panel of claim 3, wherein the display panel comprises a substrate, a first metal layer, a second metal layer and a third metal layer, wherein the second metal layer is disposed on a side of the first metal layer facing away from the substrate, and the third metal layer is disposed between the first metal layer and the second metal layer;
the first metal layer comprises the first reset signal sublines;
the second metal layer comprises the second reset signal sublines and the second bias signal sublines, and the second reset signal sublines are insulated from the second bias signal sublines; and
the third metal layer comprises the first bias signal sublines.

13. The display panel of claim 12, wherein along a direction perpendicular to a plane where the substrate is located, the first reset signal sublines at least partially overlap the first bias signal sublines.

14. The display panel of claim 12 wherein the second reset signal sublines comprise a plurality of first sub-segments extending along the second direction and arranged along the second direction, wherein the plurality of first sub-segments are electrically connected to the first reset signal sublines;
the second bias signal sublines comprise a plurality of second sub-segments extending along the second direction and arranged along the second direction, wherein the plurality of second sub-segments are electrically connected to the first bias signal sublines; and
the plurality of first sub-segments and the plurality of second sub-segments are alternately arranged along the second direction.

15. The display panel of claim 14, wherein along the second direction, a length of a first sub-segment of the plurality of first sub-segments is equal to or greater than a length of the pixel driving circuit, and a length of a second sub-segment of the plurality of second sub-segments is equal to or greater than the length of the pixel driving circuit.

16. The display panel of claim 15, wherein a number of pixel driving circuits in a same column along the second direction is N30; among signal lines in the same column and arranged along the second direction, a number of first sub-segments is N31, and a number of second sub-segments is N32; wherein N30≥N31+N32, and N30, N31 and N32 are positive integers.

17. The display panel of claim 14, wherein the plurality of first sub-segments and the plurality of second sub-segments are further alternately arranged along the first direction.

18. The display panel of claim 17, wherein the pixel driving circuit further comprises a second reset transistor, and the signal lines further comprise second reset signal lines, wherein the second reset transistor is electrically connected between a second reset signal line of the second reset signal lines and the gate of the drive transistor; and
the second metal layer further comprises the second reset signal lines, and the second reset signal lines extend along the second direction.

19. The display panel of claim 18, wherein at least one of the second reset signal lines is disposed between the first sub-segment and the second sub-segment adjacent to each other along the first direction.

20. The display panel of claim 18, wherein a number of pixel driving circuits in a same row is N40; among signal lines in the same row and arranged along the first direction, a number of first sub-segments is N41, a number of second sub-segments is N42, and a number of second reset signal lines is N43; wherein N40≥N41+N42+N43, and N40, N41, N42 and N43 are positive integers.

21. The display panel of claim 18, wherein the pixel driving circuit further comprises a first connecting portion connected between the second reset transistor and the gate of the drive transistor; and
along the first direction, the first sub-segment and the second sub-segment are disposed on a first side of the first connecting portion, and the second reset signal line is disposed on a second side of the first connecting portion, wherein the first side and the second side are different sides of the first connecting portion.

22. The display panel of claim 18, further comprising a plurality of sub-pixels, wherein the plurality of sub-pixels comprises first color sub-pixels, second color sub-pixels and third color sub-pixels;
the first color sub-pixels and the second color sub-pixels constitute a first virtual quadrilateral, a center of the first color sub-pixel is located at a first vertex of the first virtual quadrilateral, a center of the second color sub-pixel is located at a second vertex of the first virtual quadrilateral, the first vertex and the second vertex are alternately spaced, and the third color sub-pixel is located inside the first virtual quadrilateral;
the third color sub-pixels constitute a second virtual quadrilateral, a center of the third color sub-pixel is located at a vertex of the second virtual quadrilateral, and the first color sub-pixel or the second color sub-pixel is located inside the second virtual quadrilateral; and
each of the plurality of sub-pixels further comprises the pixel driving circuit; the second reset signal line overlaps the pixel driving circuit of the third color sub-pixel; the first sub-segment overlaps the pixel driving circuit of the first color sub-pixel, and the second sub-segment overlaps the pixel driving circuit of the second color sub-pixel; or the first sub-segment overlaps the pixel driving circuit of the second color sub-pixel, and the second sub-segment overlaps the pixel driving circuit of the first color sub-pixel,
wherein the first color sub-pixel, the second color sub-pixel and the third color sub-pixel are each a red sub-pixel, a green sub-pixel or a blue sub-pixel and are different from each other.

23. The display panel of claim 1, wherein the display panel comprises a display region and a non-display region at least partially surrounding the display region; wherein
the non-display region comprises a fan-out region located on a side of the display region along the first direction, and the display region comprises a first display region and a second display region, wherein the second display region is located on at least one side of the first display region along the first direction;
the fan-out region comprises a plurality of fan-out wires, and the first display region and the second display region each comprise a plurality of data lines extending along the second direction and arranged along the first direction;
each of the plurality of data lines is connected to a respective one of the plurality of fan-out wires; wherein each of the plurality of data lines in the second display region is connected to a respective fan-out wire of the plurality of fan-out wires through a connection wire; and
the connection wire is disposed in the display region and comprises a first connection wire segment extending along the first direction and a second connection wire segment extending along the second direction, wherein the first connection wire segment is electrically connected to each of the plurality of data lines in the second display region, and the second connection wire segment is electrically connected to the respective fan-out wire.

24. The display panel of claim 23, wherein the pixel driving circuit further comprises a light-emitting element, a first reset transistor and a second reset transistor; wherein
the first reset transistor is electrically connected between the drive transistor and the light-emitting element, and the second reset transistor is electrically connected to the gate of the drive transistor;
the drive transistor, the bias transistor and the first reset transistor each comprise a low-temperature polysilicon transistor; and
the second reset transistor comprises an oxide transistor.

25. The display panel of claim 23, wherein the display region further comprises auxiliary lines;
the auxiliary lines comprise at least one of a first auxiliary line extending along the first direction or a second auxiliary line extending along the second direction; and
the first auxiliary line is disposed in a same layer as the first connection wire segment and insulated from the first connection wire segment and the second connection wire segment;
and the second auxiliary line is disposed in a same layer as the second connection wire segment and insulated from the first connection wire segment and the second connection wire segment,
wherein the non-display region further comprises power buses; and the auxiliary lines are connected to the power buses.

26. The display panel of claim 25, further comprising a substrate, a first metal layer, a second metal layer, a third metal layer, a fourth metal layer and a fifth metal layer, wherein the second metal layer is disposed on a side of the first metal layer facing away from the substrate, the third metal layer is disposed between the first metal layer and the second metal layer, the fourth metal layer is disposed on a side of the second metal layer facing away from the first metal layer, and the fifth metal layer is disposed on a side of the fourth metal layer facing away from the second metal layer;
the first metal layer and the second metal layer comprise the bias signal lines; or the second metal layer and the third metal layer comprise the bias signal lines;
the fourth metal layer comprises the first auxiliary line and the first connection wire segment; and
the fifth metal layer comprises the second auxiliary line and the second connection wire segment,
wherein the signal lines further comprise at least one of first power lines or data lines, wherein a first power line of the first power lines is connected to the first electrode of the drive transistor; and
at least one of the fourth metal layer or the fifth metal layer comprises the first power lines, and the first power line is electrically insulated from the connection wire.

27. The display panel of claim 26, wherein the fifth metal layer further comprises the data lines.

28. A display device, comprising a display panel,
wherein the display panel comprises pixel driving circuits and signal lines, wherein
a pixel driving circuit of the pixel driving circuits comprises a drive transistor and a bias transistor, and the signal lines comprise bias signal lines;
the drive transistor comprises a gate, a first electrode and a second electrode; and the bias transistor is electrically connected between a bias signal line of the bias signal lines and at least one of the first electrode or the second electrode of the drive transistor; and
the bias signal lines comprise first bias signal sublines extending along a first direction and arranged along a second direction and second bias signal sublines extending along the second direction and arranged along the first direction, wherein the first direction intersects the second direction, and the first bias signal sublines and the second bias signal sublines are electrically connected.
